(19) United States
(12) Patent Application Publication
(10) Pub. No.: US 2026/0026013 A1
(43) Pub. Date: Jan. 22, 2026

(54) HYBRID BONDED MEMORY AND LOGIC DEVICES

(71) Applicant: ADEIA SEMICONDUCTOR BONDING TECHNOLOGIES INC., San Jose, CA (US)

(72) Inventors: Hong Shen, Palo Alto, CA (US); Patrick Variot, Los Gatos, CA (US); Belgacem Haba, Saratoga, CA (US); Rajesh Katkar, Milpitas, CA (US)

(21) Appl. No.: 18/777,419

(22) Filed: Jul. 18, 2024

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0652; H01L 25/18; H01L 25/50; H01L 2224/08145; H01L 2224/80895; H01L 2224/80896; H01L 2225/06548; H01L 2225/06572; H01L 2225/06589; H01L 2924/1431; H01L 2924/1436

(57) ABSTRACT

A bonded structure is disclosed. The bonded structure can include a substrate. The bonded structure can include a first memory unit disposed on the substrate. The first memory unit can have a first stack of memory dies and a first logic controller disposed on the first stack. The first logic controller can manage data communicated to or from the first stack of memory dies. The bonded structure can also include a processor die hybrid bonded to the first memory unit along a bonding interface and a vertical interconnect connecting the substrate to the processor die. The bonded structure can further include a second memory unit disposed on the substrate. The second memory unit can include a second stack of memory dies and a second logic controller disposed on the second stack. The second logic controller can manage data communicated to or from the second stack of memory dies.

### BACKGROUND

### Field

This disclosure relates to semiconductor device structures and methods. In particular, some embodiments are directed to methods and structures for providing stacked high bandwidth memory.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Semiconductor devices have increased in complexity along with the need to reduce the overall size of the devices. As semiconductor devices become more complex, the importance of minimizing latency and improving connections has increased.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In some implementations, a bonded structure can include: a substrate; a first memory unit disposed on the substrate, the first memory unit including a first stack of memory dies and a first logic controller to manage data communicated to or from the first stack of memory dies, wherein the first logic controller is disposed on the first stack of memory dies; a processor die hybrid bonded to the first memory unit along a bonding interface; and a vertical interconnect connecting the substrate to the processor die.

In some implementations, the bonded structure includes a heat sink disposed over a backside of the processor die. In some implementations, the bonded structure includes a plurality of conductive bumps disposed between the first memory unit and the substrate and the vertical interconnect and the substrate, the plurality of conductive bumps electrically connecting the first memory unit to the substrate and the vertical interconnect to the substrate. In some implementations, the plurality of conductive bumps include solder bumps.

In some implementations, the bonded structure includes a second memory unit disposed on the substrate, the second memory unit including a second stack of memory dies and a second logic controller to manage data communicated to or from the second stack of memory dies, wherein the second logic controller is disposed on the second stack of memory dies, wherein the second logic controller, and wherein the second memory unit is laterally spaced from the first memory unit on the substrate.

In some implementations, a plurality of conductive bumps is disposed between the substrate and the second memory unit, the plurality of conductive bumps electrically connecting the second memory unit to the substrate.

In some implementations, the vertical interconnect includes an interposer. In some implementations, the vertical interconnect includes through encapsulant vias (TEVs).

In some implementations, the processor die includes a first side, a second side opposite the first side, and active circuitry positioned closer to the first side than the second side, and wherein the first side is bonded to the first memory unit. In some implementations, the first logic controller of the first memory unit is hybrid bonded to the first side of the processor die. In some implementations, the first side of the processor is hybrid bonded the vertical interconnect. In some implementations, the processor die includes at least one of a system on a chip (SOC), a central processing unit (CPU), a tensor processing unit (TPU), a neural processing unit (NPU), and a graphic processing unit (GPU).

In some implementations, the vertical interconnect includes one or more layers. In some implementations, the one or more layers include at least one of silicon or glass. In some implementations, the vertical interconnect includes at least one of capacitors for a power delivery network (PDN), input/output circuits, and cache memory.

In some implementations, the vertical interconnect is hybrid bonded to the processor die along the bonding interface. In some implementations, the vertical interconnect includes a same height at the first memory unit.

In some implementations, the first memory unit and the vertical interconnect are at least partially embedded in an encapsulant. In some implementations, one or more vias extend through the encapsulant to directly connect the processor die and the substrate.

In some implementations, a bonded structure can include: a first memory unit including a first stack of memory dies and a first memory logic controller to manage data communicated to or from the first stack of memory dies, wherein the first logic controller is disposed on the first stack of memory dies; and a processor die bonded to the first logic controller along a bonding interface, wherein the first logic controller is between the first stack of memory dies and the processor die.

In some implementations, the bonded structure includes: a substrate, wherein the first memory unit is disposed on the substrate; a vertical interconnect connecting the substrate to the processor die, the vertical interconnect bonded to the processor die; and a plurality of conductive bumps disposed between the substrate and the first memory unit and the vertical interconnect, the plurality of conductive bumps electrically connecting the first memory unit and the vertical interconnect to the substrate. In some implementations, the plurality of conductive bumps include solder bumps. In some implementations, the vertical interconnect is hybrid bonded to the processor die along the bonding interface. In some implementations, the first memory logic controller is hybrid bonded to the processor die along the bonding interface.

In some implementations, the bonded structure includes a second memory unit disposed on the substrate, the second memory unit including a second stack of memory dies and a second memory logic controller to manages data communicated to or from the second stack of memory dies wherein the second memory logic controller is disposed on the second stack of memory dies, wherein the second memory logic controller is bonded to the processor die along the bonding interface, and wherein the second memory unit is laterally spaced from the first memory unit on the substrate. In some implementations, the vertical interconnect is positioned between the first memory unit and the second memory unit. In some implementations, the plurality of conductive bumps is further disposed between the substrate and the second memory unit, the plurality of conductive bumps electrically connecting the second memory unit to the substrate. In some implementations, the second stack of memory dies and the second logic controller are hybrid bonded to one another.

In some implementations, the vertical interconnect includes an interposer. In some implementations, the vertical interconnect includes through encapsulant vias (TEVs). In some implementations, the vertical interconnect includes one or more layers. In some implementations, the one or more layers include at least one of silicon or glass. In some implementations, the vertical interconnect includes at least one of capacitors for a power delivery network (PDN), input/output circuits, and cache memory.

In some implementations, the bonded structure includes a heat sink disposed over a backside of the processor die. In some implementations, the first stack of memory dies and the first logic controller are hybrid bonded to one another. In some implementations, the processor die is hybrid bonded to the first logic controller along the bonding interface.

In some implementations, the processor die includes a first side, a second side opposite the first side, and active circuitry positioned closer to the first side than the second side, and wherein the first side is bonded to the first memory unit. In some implementations, the first memory logic controller of the first memory unit is hybrid bonded to the first side of the processor die. In some implementations, the processor die includes at least one of a system on a chip (SOC), a central processing unit (CPU), a tensor processing unit (TPU), a neural processing unit (NPU), and a graphic processing unit (GPU). In some implementations, the processor die is electrically connected to the first logic controller. In some implementations, the first memory unit is at least partially embedded in an encapsulant. In some implementations, one or more vias extend through the encapsulant and are configured to directly connect the processor die to a substrate.

In some implementations, a bonded structure can include: a processor die including a first side, a second side opposite the first side, and active circuitry positioned closer to the first side than the second side; a first memory unit bonded to the first side of the processor die along a bonding interface, the first memory unit including a first stack of memory dies and a first logic controller to manages data communicated to or from the first stack of memory dies, wherein the first logic controller is disposed on the first stack of memory dies; and a heat sink disposed over the second side of the processor die.

In some implementations, the bonded structure includes: a substrate, wherein the first memory unit is disposed on the substrate; a vertical interconnect connecting the substrate to the processor die, the vertical interconnect bonded to the processor die along the bonding interface; and a plurality of conductive bumps disposed between the substrate and the memory unit and between the substrate and the vertical interconnect, the plurality of conductive bumps electrically connecting the memory unit and the vertical interconnect to the substrate. In some implementations, the plurality of conductive bumps include solder bumps. In some implementations, the vertical interconnect is hybrid bonded to the processor die.

In some implementations, the bonded structure includes a second memory unit disposed on the substrate, the second memory unit including a second stack of memory dies and a second logic controller to manage data communicated to or from the second stack of memory dies, wherein the second logic controller is disposed on the second stack of memory dies, wherein the second memory unit is laterally spaced from the first memory unit on the substrate. In some implementations, the vertical interconnect is positioned between the first memory unit and the second memory unit. In some implementations, the plurality of conductive bumps is disposed between the substrate and the second memory unit, the plurality of conductive bumps electrically connecting the second memory unit to the substrate.

In some implementations, the vertical interconnect includes an interposer. In some implementations, the vertical interconnect includes through encapsulant vias (TEVs). In some implementations, the vertical interconnect includes one or more layers. In some implementations, the one or more layers include at least one of silicon or glass. In some implementations, the vertical interconnect includes at least one of capacitors for a power delivery network (PDN), input/output circuits, and cache memory.

In some implementations, the first stack of memory dies and the first logic controller are hybrid bonded to one another. In some implementations, the second stack of memory dies and the second logic controller are hybrid bonded to one another. In some implementations, the processor die is hybrid bonded to the first logic controller along a bonding interface.

In some implementations, the processor die includes at least one of a system on a chip (SOC), a central processing unit (CPU), a tensor processing unit (TPU), a neural processing unit (NPU), and a graphic processing unit (GPU).

In some implementations, the first memory unit and the vertical interconnect are at least partially embedded in an encapsulant. In some implementations, one or more vias extend through the encapsulant to directly connect the processor die to a substrate.

In some implementations, a bonded structure can include: a connector unit; a first processor die bonded to the connector unit along a first bonding interface; a second processor die bonded to the connector unit along a second bonding interface; and a first memory unit bonded to the first processor die along the first bonding interface, the first memory unit including a first stack of memory dies and a first logic controller to manage data communicated to or from the first stack of memory dies, wherein the first logic controller is disposed on the first stack of memory dies; wherein the connector unit is configured to connect the first processor die and the second processor die, the connector unit serving as a bridge for lateral communication between the first processor die and the second processor die.

In some implementations, the bonded structure includes: a substrate, wherein the first memory unit and the connector unit are disposed on the substrate; and a plurality of conductive bumps disposed between the substrate and the first memory unit and the connector unit, the plurality of conductive bumps electrically connecting the first memory unit and the connector unit to the substrate. In some implementations, the plurality of conductive bumps include solder bumps.

In some implementations, the bonded structure includes a second memory unit disposed on the substrate, the second memory unit including a second stack of memory dies a second logic controller to manage data communicated to or from the second stack of memory dies, wherein the second logic controller is disposed on the second stack of memory dies, wherein the second memory unit is bonded to the second processor die along the second bonding interface, and wherein the second memory unit is laterally spaced from the first memory unit on the substrate. In some implementations, the connector unit is positioned between the first memory unit and the second memory unit. In some implementations, the plurality of conductive bumps is disposed between the substrate and the second memory unit, the plurality of conductive bumps electrically connecting the second memory unit to the substrate.

In some implementations, the connector unit includes an interposer. In some implementations, the connector unit includes through encapsulant vias (TEVs). In some implementations, the connector unit includes one or more layers. In some implementations, the one or more layers include at least one of silicon or glass. In some implementations, the vertical interconnect includes at least one of capacitors for a power delivery network (PDN), input/output circuits, and cache memory. In some implementations, the bonded structure includes a heat sink disposed over a backside of the processor die.

In some implementations, the first processor die and the second processor die include a first side, a second side opposite the first side, and active circuitry positioned closer to the first side than the second side, and wherein the first and second bonding interface is disposed on the first side of the first processor die and the second processor die.

In some implementations, the first memory unit and the connector unit are at least partially embedded in an encapsulant. In some implementations, one or more vias extend through the encapsulant to directly connect the processor die to a substrate.

In some implementations, a bonded structure can include: a substrate; a first memory unit disposed on the substrate, the first memory unit including a first stack of memory dies a first logic controller to manage data communicated to or from the first stack of memory dies, wherein the first logic controller is disposed on the first stack of memory dies; a second memory unit disposed on the substrate, the second memory unit including a second stack of memory dies and a second logic controller to manage data communicated to or from the second stack of memory dies, wherein the second logic controller is disposed on the second stack of memory dies, wherein the second memory unit is laterally spaced from the first memory unit on the substrate; a vertical interconnect disposed on the substrate; and a processor die including a first side, a second side opposite the first side, and active circuitry positioned closer to the first side than the second side, the first side hybrid bonded to at least one of the first memory unit, the second memory unit, and the vertical interconnect.

In some implementations, the processor die includes at least one of a system on a chip (SOC), a central processing unit (CPU), and a graphic processing unit (GPU).

In some implementations, the vertical interconnect is positioned between the first memory unit and the second memory unit. In some implementations, the vertical interconnect including one or more layers corresponding to a height of the first memory unit and the second memory unit. In some implementations, the one or more layers include at least one of silicon or glass. In some implementations, the vertical interconnect includes at least one of capacitors for a power delivery network (PDN), input/output circuits, cache memory.

In some implementations, the bonded structure includes a plurality of conductive bumps disposed between the first memory unit and the substrate, the second memory unit and the substrate, and the vertical interconnect and the substrate, the conductive bumps electrically connecting the first memory unit to the substrate, the second memory unit to the substrate, and the vertical interconnect to the substrate. In some implementations, the plurality of conductive bumps include solder bumps.

In some implementations, the bonded structure includes a heat sink disposed over second side of the processor die.

In some implementations, the vertical interconnect includes one or more through encapsulant vias to route signals from the substrate to the processor die.

In some implementations, the first memory unit, the second memory unit, and the vertical interconnect are at least partially embedded in an encapsulant. In some implementations, one or more vias extend through the encapsulant to directly connect the processor die and the substrate.

In some implementations, a bonded structure can include: a substrate; a first memory unit disposed on the substrate, the first memory unit including a first stack of memory dies and a first logic controller to manage data communicated to or from the first stack of memory dies, wherein the first logic controller is disposed on the first stack of memory dies; a second memory unit disposed on the substrate, the second memory unit including a second stack of memory dies and a second logic controller to manage data communicated to or from the second stack of memory dies, wherein the second logic controller is disposed on the second stack of memory dies, wherein the second memory unit is laterally spaced from the first memory unit on the substrate; a connector unit disposed on the substrate; a first processor die hybrid bonded to the first memory unit and the connector unit along a first bonding interface; and a second processor die hybrid bonded to the second memory unit and the connector unit along a second bonding interface; wherein the connector unit electrically connects the first processor die and the second processor die.

In some implementations, the first processor die and the second processor die include a first side, a second side opposite the first side, and active circuitry positioned closer to the first side than the second side, and wherein the first and second bonding interface is disposed on the first side of the first processor die and the second processor die. In some implementations, the first processor die includes at least one of a system on a chip (SOC), a central processing unit (CPU), and a graphic processing unit (GPU). In some implementations, the second processor die includes at least one of a system on a chip (SOC), a central processing unit (CPU), and a graphic processing unit (GPU).

In some implementations, the connector unit is positioned between the first memory unit and the second memory unit. In some implementations, the connector unit including one or more layers corresponding to a height of the first memory unit and the second memory unit. In some implementations, the one or more layers include at least one of silicon or glass. In some implementations, the connector unit includes at least one of capacitors for a power delivery network (PDN), input/output circuits, cache memory.

In some implementations, the bonded structure includes a plurality of conductive bumps disposed between the first memory unit and the substrate, between the second memory unit and the substrate, and between the connector unit and the substrate, the conductive bumps electrically connecting the first memory unit to the substrate, electrically connecting the second memory unit to the substrate, and electrically connecting the connector unit to the substrate.

In some implementations, the first memory unit and the connector unit are at least partially embedded in an encapsulant. In some implementations, one or more vias extend through the encapsulant to directly connect the first and second processor dies and the substrate.

In some implementations, a bonded structure can include: a substrate; a processor die including a first side and a second side opposite the first side, the first side bonded to the substrate along a bonding interface; a first memory unit disposed on the second side of the processor die, the first memory unit including a first stack of memory dies and a first logic controller to manage data communicated to or from the first stack of memory dies, wherein the first logic controller is disposed on the first stack of memory dies; a second memory unit disposed on the on the second side of the processor die, the second memory unit including a second stack of memory dies and a second logic controller to manage data communicated to or from the second stack of memory dies, wherein the second logic controller is disposed on the second stack of memory dies; and a die disposed on the second side of the processor die.

In some implementations, the processor die includes active circuitry positioned closer to the first side than the second side, and wherein the first side is bonded to the substrate. In some implementations, the bonded structure includes one or more through silicon vias extending through the processor die. In some implementations, the bonded structure includes one or more through silicon vias extending through a periphery of the processor die.

In some implementations, the die includes a power redistribution element. In some implementations, the bonded structure includes one or more wire bonds electrically connected to the power redistribution element to transfer power to the power redistribution element. In some implementations, the power redistribution element includes at least one of capacitors for a power delivery network (PDN), input/output circuits, cache memory.

In some implementations, the processor die includes at least one of a system on a chip (SOC), a central processing unit (CPU), and a graphic processing unit (GPU). In some implementations, the first memory unit is disposed on a first end of the processor die, the second memory unit is disposed on a second end opposite the first end of the processor die, and the die is positioned between the first memory unit and the second memory unit. In some implementations, the die includes a cooling cavity configured for removal of heat from the processor die. In some implementations, the die includes a dummy die.

In some implementations, the bonded structure includes a heat sink disposed over the first memory unit, the second memory unit, and the die.

In some implementations, the processor die is bonded to the substrate by a plurality of conductive bumps. In some implementations, the plurality of conductive bumps include solder bumps.

In some implementations, the bonded structure includes a first reconstituted die including the processor and one or more through silicon vias (TSVs) extending through a periphery of the first reconstituted die. In some implementations, the bonded structure includes a second reconstituted die comprising the first memory unit, the second memory unit, and the die, wherein the second reconstituted die is hybrid bonded to the first reconstituted die. In some implementations, the one or more TSVs route signals from the processor die to the first memory unit and the second memory unit. In some implementations, the bonded structure includes a first reconstituted die including the processor and one or more through silicon vias extending through a periphery of the first reconstituted die. In some implementations, the bonded structure includes a second reconstituted die including the first memory unit, the second memory unit, and the die, wherein the second reconstituted die is hybrid bonded to the first reconstituted die.

In some implementations, the one or more through silicon vias route signals from the processor die to the first memory unit and the second memory unit. In some implementations, the one or more through silicon vias route signals from the processor die to the first memory unit and the second memory unit. In some implementations, the processor die includes a thinned processor die.

In some implementations, a method for forming a bonded structure can include: providing a connector unit having a first side and a second side opposite the first side; bonding a first processor die to the connector unit along a first bonding interface; bonding a second processor die to the connector unit along a second bonding interface; and a first memory unit bonded to the first processor die along the first bonding interface, the first memory unit including a first stack of memory dies and a first logic controller to manage data communicated to or from the first stack of memory dies, wherein the first logic controller is disposed on the first stack of memory dies; wherein the connector unit is configured to connect the first processor die and the second processor die, the connector unit serving as a bridge for lateral communication between the first processor die and the second processor die.

In some implementations, the method includes bonding a second memory unit to the second processor die along the second bonding interface, the second memory unit including a second stack of memory dies and a second logic controller to manage data communicated to or from the second stack of memory dies, wherein the second logic controller is disposed on the second stack of memory dies. In some implementations, bonding the second memory unit to the second processor die includes hybrid bonding.

In some implementations, bonding the first memory unit and the second side of the connector unit to a substrate. In some implementations, bonding the first processor die and the second processor die to the connector unit includes hybrid bonding. In some implementations, bonding the first memory unit to the first processor die includes hybrid bonding.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a side schematic sectional view of a conventional bonded structure with high bandwidth memories stacked around a periphery of a processor.

FIG. 1B illustrates a top schematic perspective view of the bonded structure shown in FIG. 1A.

FIG. 2 illustrates a top schematic perspective view of a bonded structure with high bandwidth memories stacked on top of a processor.

FIG. 3 illustrates a schematic side sectional view of an example implementations of a bonded structure.

FIG. 4 illustrates a schematic bottom view of the bonded structure shown in FIG. 3.

FIG. 5 illustrates a schematic side sectional view of another example implementation of a bonded structure.

FIGS. 6 and 7 illustrate schematic perspective views of an exemplary implementation of a bonded structure comprising reconstituted high bandwidth memory units.

FIG. 8 illustrates a schematic perspective view of an exemplary implementation of a bonded structure having a backside power delivery network (B-PDN) and power delivery die disposed over a processor.

FIGS. 9 and 10 illustrate schematic perspective views of another exemplary implementations of a bonded structure comprising reconstituted high bandwidth memory units and multiple processors dies.

FIG. 11 illustrates a schematic side view of another exemplary implementation of a bonded structure.

FIG. 12 illustrates a schematic side view of the bonded structure of FIG. 10 in which the memory units and die are encapsulated to form a reconstituted layer.

FIG. 13 is a graphical flow diagram illustrating an example process for assembling a bonded structure.

FIG. 14 is a graphical flow diagram illustrating an example process for assembling a connector unit and/or a vertical interconnect.

FIG. 15 is a graphical flow diagram illustrating another example process for assembling a connector unit and/or a vertical interconnect.

FIG. 16A is a schematic cross-sectional side view of two elements prior to direct hybrid bonding.

FIG. 16B is a schematic cross-sectional side view of a bonded structure including the two elements shown in FIG. 16A after direct hybrid bonding.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and includes other uses of the inventions and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments can comprise several novel features. No single feature is solely responsible for its desirable attributes or is essential to practicing the inventions herein described.

There is significant demand for higher memory bandwidth and higher memory capacity. Providing high speed, high bandwidth connections between memory and processors can be important for some applications. For example, when training an artificial intelligence or machine learning model, performing complex graphical operations, or carrying out other data-intensive tasks, processors such as central processing units (CPUs), graphical processing units (GPUs), tensor processing units (TPUs), neural processing units (NPUs), field programmable gate arrays (FPGAs), application-specific integrated circuits (ASICs), and so forth can spend a significant amount of time idle while waiting for data, which can negatively impact performance and increase the time it takes to complete computing tasks.

Conventional high bandwidth memory (HBM) implementations use stacked memory units positioned adjacent to and in close proximity to the processor. For example, memory dies (e.g., dynamic random access memory (DRAM) dies) can be stacked and connected to a processor (e.g., a GPU or CPU) through a carrier (e.g., a silicon interposer). The memory dies can comprise silicon chips that house the actual memory cells in a memory module, where each memory die contains an array of memory cells that store data. In some embodiments, a logic controller die can be present in the stack. A typical HBM stack can comprise a plurality of (e.g., four, eight, twelve, sixteen, etc.) DRAM dies and a logic layer (e.g., a logic controller die). In some implementations, memory units can be stacked directly on a processor and connected to the processor using through silicon vias. When the processor executes a program, the processor fetches instructions from the main memory, which is used by a device (e.g., computer, mobile device, etc.) as the primary storage to hold data and instructions that are being used by the processor. If the required data is not found in the cache of the main memory, the processor sends a request to the logic controller die, which then accesses the appropriate memory die (e.g., the DRAM dies). The logic controller can manage the communication between the processor and the memory dies and optimizing the data transfer, which can minimize latency and maximize bandwidth. The data is transferred back to the processor to then execute the instructions.

HBM can offer several advantages as compared to using separate memory that is socketed or soldered to a PCB. For example, power consumption can be lower, form factors can be smaller, thermal performance can be better and bandwidth can be significantly higher. However, there are several drawbacks and limitations of current HBM implementations. For example, memory dies are typically fabricated separately and contact pads are formed on the memory dies. The dimensions of the contact pads can be, for example, about 25 micrometers and can have a pitch of about 55 micrometers. These large feature sizes can limit the total number of interconnects that can be formed within a given area. Additionally, to achieve high bandwidth and low latency, it can be important to locate the memory dies as close to the processor as possible. For example, while socketed memory in a desktop or server may be several centimeters from a processor, HBM modules are typically within a few millimeters of the processor, and greater distances can significantly worsen performance. These limitations can negatively impact both the capacity of HBM and the available bandwidth.

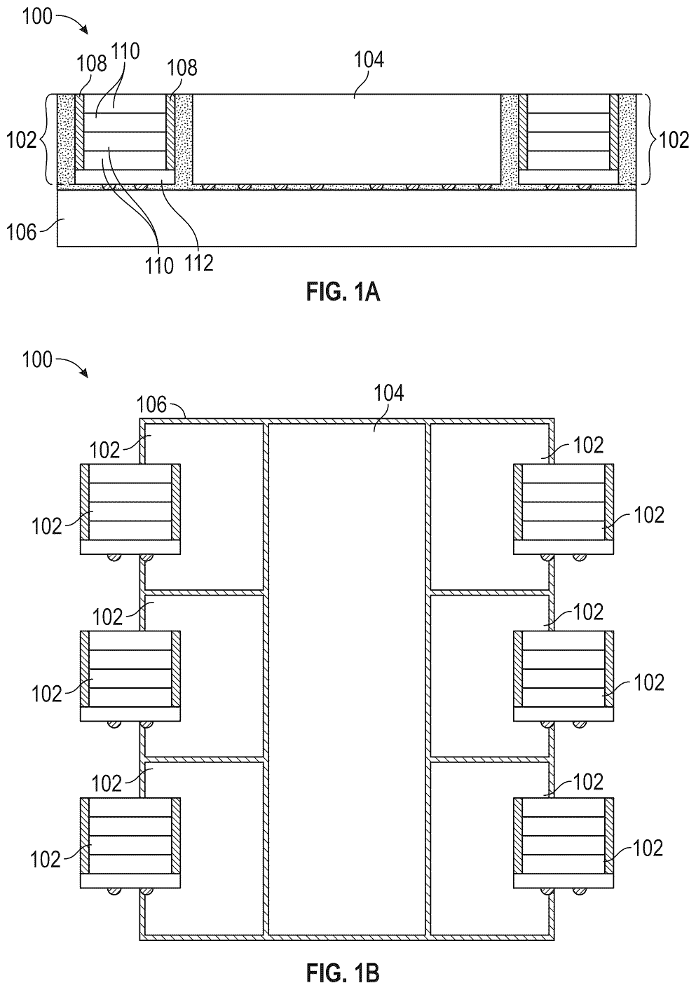

FIG. 1A illustrates a conventional bonded structure 100 with HBMs in which stacked memory modules 102 (e.g., four stacked memory dies 110 on top of a logic controller die 112) are arranged around the periphery of a processor 104 (e.g., a CPU or GPU). The memory modules 102 can be encapsulated by an encapsulant 108, such as inorganic dielectric (e.g., silicon oxide, silicon nitride, etc.) or an organic dielectric (e.g., a polymeric molding compound). In some implementations, the memory modules 102 can be encapsulated by an encapsulant 108, such as organic dielectric or encapsulant 108 (e.g. epoxy mold compound, resin, etc.). The memory dies 110 in the memory modules 102 can be connected via flip chip, micro-bumps, hybrid bonding, etc. The memory modules 102 and the processor 104 are shown to be mounted to an interposer 106 providing electrical communication (e.g. using flip chip, micro-bumps, hybrid bonding, etc.). As high performance processor 104 (e.g. GPU) and memory modules 102 (e.g. HBM) are laterally mounted on the interposer 106, both are exposed at the top of the package and can be provided with a heat spreader apparatus (not shown in FIG. 1A) for thermal extraction, especially from high performance processor. Interposer 106 can be mounted to an organic substrate (e.g. PCB). The interposer 106 can serves as an intermediary between the different semiconductor devices (e.g., memory modules 102 and processor 104), enabling connections between them. The interposer 106 can comprise a thin substrates made of materials such as silicon or glass, with embedded wiring and vias (connections) in a dielectric. The memory modules 102 can be a few tens or few hundred microns away from the processor 104 connected by long transmission lines between their respective interface contacts (e.g. HBM interface contacts), which leads to transmission losses due to latency. FIG. 1B illustrates a top schematic perspective view of the bonded structure 100 illustrating a layout of the components shown in FIG. 1A. The implementations shown in FIGS. 1A and 1B have significant drawbacks. While any number of the memory modules 102 (i.e., memory stacks) can be added to the configuration, the memory modules 102 are located at a relatively large distance from the processor 104, negatively impacting performance. Thus, there is a need for approaches that can decrease separation of memory modules and processors while maintaining or increasing performance. Some implementations herein can significantly improve the transmission of signals between HBMs and processors. Advantageously, some implementations herein can improve the transmission of signals without requiring large interposers or bridges connecting the HBM and processors.

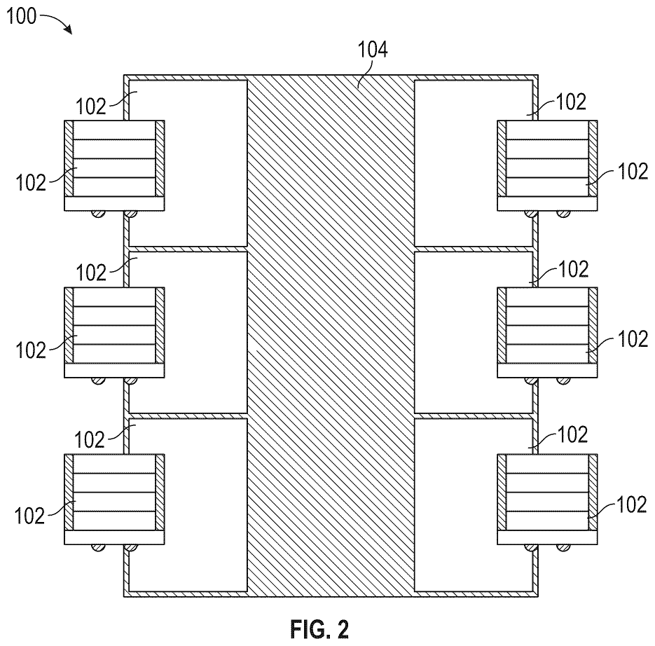

One approach, as depicted in FIG. 2, is to vertically attach memory modules 102 directly on top of the processor die 104 (e.g. CPU, GPU, etc.) without the need of interposer (e.g., interposer 106) or a bridge die providing lateral electrical connections between the memory modules 102 and the processor die 104. In such implementations, the electrical connection between the memory modules 102 and processor 104 can be established using through silicon vias formed (e.g., drilled) in the processor 104. The path length of the electrical connection in such direct vertical stack approach is now reduced just a few tens of microns (or equivalent to the thickness of the processor 104) as I/O interfaces between the memory modules 102 and processor 104 are now aligned and separated by thickness of the processor 104 only. In FIGS. 1A-B, the separation due to lateral placement had about 3 mm to 6 mm long wiring on the interposer/bridge. In some implementations, both memory modules 102 and processor 104 can be mounted in face down orientation (e.g. active side facing down) and contacts are formed via back to face connections (e.g. back of processor 104 to face of a logic/controller die of memory modules 102). One drawback of this assembly in FIG. 2 is the heat extraction from the processor die 104 since only a limited area of the processor die 104 is now exposed to heat spreader assembly (while rest is buried below the memory stack). Such heat spreader assembly is also challenging as the processor die 104 is now 100s of micron below the top of the effective package (as memory modules 102 itself can be a few 100 micron tall).

Another such vertical approach is to stack HBM units (e.g., stacks of four DRAM dies) on top of one other and a logic/controller die, for example, as described in U.S. patent application Ser. No. 18/052,399, filed Nov. 3, 2022, the entire contents of which are incorporated by reference herein in their entirety and for all purposes. Two or more memory units can be stacked on top of one another to form a memory module. To accommodate the large number of input/output connections to support multiple memory units in a single memory module, it can be important to have small contacts and small pitches. Accordingly, rather than forming connections using relatively large metal bumps as can be done in conventional approaches, direct hybrid bonding, as described in more detail herein, can be used to bond and form electrical connections between the components of the bonded structure. Direct dielectric bonding, non-adhesive techniques, such as a ZiBond® direct bonding technique or a DBIR hybrid bonding technique, both available from Invensas Bonding Technologies, Inc. (formerly Ziptronix, Inc.), a subsidiary of Xperi Corp (see for example, U.S. Pat. Nos. 6,864,585 and 7,485,968, which are incorporated herein in their entirety) can be used.

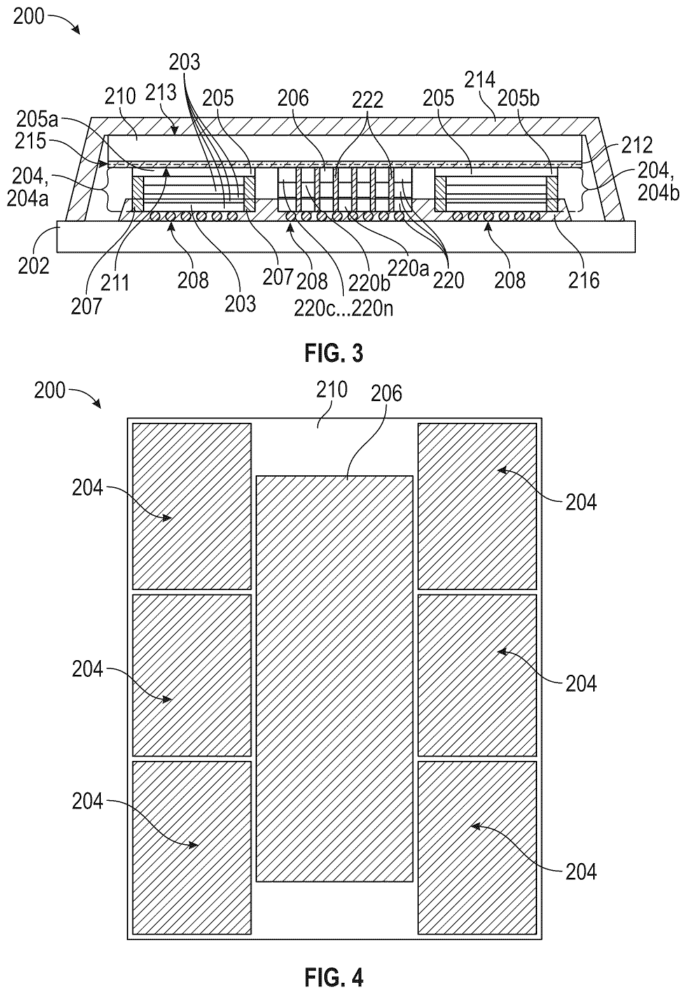

FIG. 3 illustrates a schematic side sectional view of an example implementations of a bonded structure 200. In FIG. 3, the bonded structure 200 can include a substrate 202. The substrate 202 can comprise a substrate having a nonconductive or insulating base substrate with conductive routing traces (not shown) (e.g., at least partially embedded traces), such as a laminate substrate, a printed circuit board (PCB) substrate, a semiconductor interposer, redistribution layers (e.g. in fan out wafer level packages), a reconstituted structure with one or more die(s) at least partially embedded in an encapsulant, a flexible substrate comprising a polymer with embedded traces, an integrated device die or wafer, or any other suitable substrate. The conductive routing traces can laterally and vertically transfer signals through the substrate 202 in various implementations, to connect to terminals on a bottom side of the substrate 202.

The bonded structure 200 can also include a memory unit 204 disposed (e.g., bonded) to the substrate 202, wherein each memory unit 204a, 204b comprises a plurality of (e.g., two, three, four, five, etc.) memory dies 203 (e.g., DRAM dies) hybrid bonded to and stacked on one another. Through substrate vias (TSVs) (e.g., through silicon vias, or TSVs) can extend through the memory dies 203 to provide communication with a logic controller 205 (also referred to herein as a “logic controller die” or core die). The memory units 204 can be encapsulated by an encapsulant 207, such as inorganic dielectric (e.g., silicon oxide, silicon nitride, etc.) or an organic dielectric (e.g., a polymeric molding compound). In some implementations, the memory units 204 can be bonded to a prepared surface of the substrate 202 using a ZIBOND® or DBIR hybrid bonding technique, or the like (e.g., without adhesive or an intervening layer). In some implementations, the memory units 204 can be bonded to a the substrate 202 using flip bonding or micro-bumping. Each of the memory units 204 can further include a logic controller 205. The logic controller 205 can manage data communicated to or from the stack of memory dies (e.g., data sent to and/or received from the processor or other devices). In some implementation, the first logic controller 205a and the second logic controller 205b of the first memory unit 204a and/or second memory unit 204b, respectively, can be disposed on (e.g., stacked on top of) the stack of memory dies. The memory units 204 can be laterally spaced from one another on the substrate 202.

A vertical interconnect to create connections between different components, such as vertical interconnect unit 206 shown in FIG. 3, can also be disposed (e.g., bonded, such as directly bonded) on the substrate 202 to provide vertical electrical communication between the processor die 210 and the substrate 202. The vertical interconnect can allow for the transmission of signals or power vertically through the layers of the bonded structure 200, rather than solely horizontally along a surface. The vertical connection between the substrate 202 and the processor die 210 can be formed in various ways, including TSVs extending through the vertical interconnect unit 206, copper pillars extending through an encapsulant (e.g., copper pillars extending through layers 220 comprising an encapsulant), and/or microbumps in contact with the vertical interconnect unit 206 and/or vertical interconnects 222 of the vertical interconnect unit 206 to establish a connection between the vertical interconnect unit 206 and the substrate 202. The vertical interconnects can enable high-speed data transmission, efficient signal delivery, efficient power distribution, and/or compact integration of components. In some implementations, the vertical interconnect unit 206 is positioned laterally between the memory units 204, the first memory unit 204a and second memory unit 204b. In some implementations, the vertical interconnect unit 206 can include a plurality of layers 220 (e.g., one or more dies, laminate layers, etc.) directly bonded to one another. In some implementations, the vertical interconnect unit 206 can include a number of dies such that the height of the dies corresponds to a height of the memory units 204, first memory unit 204a and the second memory unit 204b. For example, a memory die 203 in the memory unit 204 could be approximately 40-50 μm thick. Hence, a stack of four memory dies 203 forming a memory unit 204 could be approximately 200-300 μm thick (which can also include the logic controller 205). In another example, a memory units 204 could be approximately 350-450 μm thick or about a stack of eight memory dies 203, etc. Forming a vertical unit from solely a single memory die 203 would not be practical due to tall TSVs. Thus, several dies are to be stacked (e.g. each die could be 50-200 μm thick). In some implementations, the vertical interconnect unit 206 can comprise an interposer. In some implementations, the vertical interconnect unit 206 can comprise a plurality of smaller vertical interconnect units (e.g., layers 220 bonded together) combined together to form the vertical interconnect unit 206.

The vertical interconnect unit 206 can further include vertical interconnects 222 (e.g., TSVs, through dielectric vias (TDVs), and/or through encapsulant vias (TEVs)) formed within the stack of layers 220. By providing direct pathways for signals, power, and heat dissipation between stacked layers 220, vertical interconnects 222 can allow for data transfer, efficient power distribution, and thermal management. The layers 220 can include a base layer 220a, a second layer 220b, and additional layers 220c . . . 220n. The layers 220 of the vertical interconnect unit 206 can comprise any suitable material such as a semiconductor material (e.g., silicon) or one or more layers of dielectric material (e.g., glass). In other implementations, the layers 220 of the vertical interconnect unit 206 can comprise an encapsulant and the vertical interconnects 222 can comprise through dielectric vias (TDVs) (e.g., through encapsulant vias (TEVs), or TDVs). In some implementations, the layers 220 can be bonded (e.g., directly bonded) and/or formed in build-up deposition processes. For example, in direct bonding implementations, the layers 220 can be hybrid bonded to one another such that portions of the vertical interconnects 222 (e.g., vias) are provided in each layer 220, and opposing dielectric surfaces are directly bonded. Opposing portions of the vertical interconnects 222 (e.g., vias) can be directly bonded as well to form hybrid bonds between the layers. In other implementations, dielectric layers 220 can be directly bonded, and, subsequently, vias can be formed through the dielectric layers. The vertical interconnect unit 206 can also include passive devices, such as capacitors for a smooth ripple free power delivery network (PDN) to the processor die 210. The PDN can regulate the power (i.e., voltage) received by the vertical interconnect unit 206 and distribute the correct voltage to the processor die 210. In some implementations, the vertical interconnect unit 206 can further include input/output circuits to facilitate the transfer of data between the substrate 202 and the processor die 210. In some implementations, the vertical interconnect unit 206 can further include cache memory or storage memory for temporarily storing data and/or instructions to assist with processing. A backside of each layer 220 of the vertical interconnect unit 206 can further include routing layers (e.g., redistribution (RDL) layers, circuitry and/or components) to facilitate routing and reduce traffic in the vertical interconnect unit 206.

In some implementations, the memory units 204 and vertical interconnect unit 206 can be mounted to the substrate 202 via conductive bumps 208, which can be disposed between the substrate 202 and the memory units 204a, 204b, and the vertical interconnect unit 206. The conductive bumps 208 can electrically and mechanically connect the first memory unit 204a, the second memory unit 204b, and the vertical interconnects 222 of the vertical interconnect unit 206 to the substrate 202. In some implementations, the conductive bumps 208 comprise solder bumps and/or another conductive adhesive. In some implementations, an underfill 216 is disposed between the substrate 202 and the memory units 204a, 204b, and the vertical interconnect unit 206. The underfill 216 can comprise an epoxy and/or polymer material to fill a gap between the substrate 202 and the memory units 204 and the vertical interconnect unit 206. For example, the underfill 216 can be applied to cover microbumps connecting the vertical interconnect unit 206 to the substrate 202. The underfill 216 can provide mechanical support to solder joints, enhances thermal management, improves reliability by reducing solder joint failure, and/or protect against environmental factors like moisture and/or dust. In other implementations, the memory units 204 and the vertical interconnect unit 206 can be bonded (e.g., hybrid bonded) to the substrate 202. In some embodiments, memory stacks 204 and vertical interconnect unit 206 are mounted on the processor die (or wafer) 210 and then encapsulated, prior to attaching this molded stack (comprising processor 210, memory stack 204. and vertical interconnect unit) 206 to the substrate 202.

The bonded structure 200 can further include a processor die 210 having a bonding layer 212. The processor die 210 can be disposed (e.g., bonded) over the memory units 204 and/or the vertical interconnect unit 206. The bonding layer 212 of the processor die 210 can be bonded along a bonding interface 215 to bonding layers (not shown) of on an upper surface of the logic controllers 205 and/or the vertical interconnect unit 206. The bonding layers can comprise prepared hybrid bonding surfaces. In some implementations, the processor die 210 is bonded to the logic controller 205 of the memory units 204 such that the logic controller 205 is between the stack of memory dies 203 of the memory units 204 and the processor die 210. The processor die 210 can include a first side 211, a second side 213 opposite the first side 211, and active circuitry (not shown) positioned closer to the first side 211 than the second side 213 (e.g., as used herein the first side 211 can be considered an active side of the processor die 210). In some implementations, the first side 211 is bonded to the memory units 204 and the vertical interconnect unit 206 (i.e., in a facedown configuration). Additionally, in some implementations, the processor die 210 can be directly hybrid bonded to the memory units 204 and the vertical interconnect unit 206 along the bonding interface 215. Nonconductive and conductive regions of the processor die 210, the memory units 204, and the vertical interconnect unit 206 can be directly bonded without intervening adhesives and without application of external pressure. The processor die 210 can be electronically and mechanically connected to the memory units 204 and the vertical interconnect unit 206.

The processor die 210 can comprise at least one of a system on a chip (SOC), a central processing unit (CPU), a graphic processing unit (GPU), a tensor processing unit (TPU), a neural processing unit (NPU), or any other suitable type of processor. The processor die 210 can be connected to the substrate 202 via the vertical interconnect unit 206. The vertical interconnect unit 206 can include any number of input/output connections for connecting the processor die 210 to the substrate 202. Additionally, periphery circuits such as power, ground, and/or clocks can be routed through the vertical interconnect unit 206 with larger TSVs which can save space within the memory units 204 since the connections are located in the vertical interconnect unit 206. By hybrid bonding the processor die 210 to the memory units 204 and/or the vertical interconnect unit 206, the need for an interposer and/or bridge is eliminated for processor/HBM interactions. Thus, the logic controller 205 of the memory units 204 can be attached to each other without the need of an intermediate interposer (e.g., interposer 106) needing 3 mm to 6 mm long interposer connection (as shown in FIG. 1A) or even TSV connections through the processor die 210 (as expected in FIG. 2). The respective I/O interfaces of the logic controller 205 and processor die 210 are not abutted against each other to effectively form the shortest electrical connections. In some implementations, the electrical connections can also be facilitated by flip-chip as well, however, hybrid bonding offers additional advantages over a flip-chip configuration. To help facilitate the shortening of the electrical path, the logic controller 205 and the processor die 210 can bonded in a face-to-face orientation (e.g., the active circuitry of processor die 210 is face down and the active circuitry of the logic controller 205 of the memory units 204 face up), which provides for shorter interconnects (e.g., the distance that signal(s) travels is reduced, resulting in lower latency and higher speed) and higher bandwidth (i.e., the proximity of the circuits enables higher data transfer rates). Therefore, stacking the memory units 204 directly on the processor die 210 can reduce transmission losses and thus improve latency.

A heat sink 214 (e.g., heat sink bar and/or spreader) can be mounted to the substrate 202 and disposed over the processor die 210 to dissipate heat generated by the processor die 210 and prevent overheating. The heat sink 214 can contact a backside (i.e., the second side 213 when the first side 211 is bonded to the memory units 204 and the vertical interconnect unit 206) of the processor die 210. As the processor die 210 can generate the most heat of the components of the bonded structure 200, the heat sink 214 can be proximate to the warmest component (i.e., the processor die 210) to optimize heat transfer away from the bonded structure 200. The arrangement of FIG. 3 is in contrast to the configuration of FIG. 2, where, in FIG. 2, only a partial surface of the processor 104 could be exposed to a heat spreader since the processor die 104 is now hundreds of micron below the top of the effective package (as memory modules 102 itself can be a few 100 micron tall), while the rest is buried below the memory stack.

The heat sink 214 can comprise a thermally conductive material, such as aluminum or copper, with a large surface area to efficiently transfer heat away from the processor die 210. In some implementations, the heat sink 214 can be attached to the processor die 210 using a thermally conductive adhesive and/or thermal paste. Once the heat is transferred to the heat sink 214, the heat then dissipates into the surrounding air through convection. As shown in FIG. 3, the heat sink 214 can include a vertical wall or legs (not parallel to the substrate 202) extending up from the substrate 202. The heat sink 214 can at least partially (e.g. completely in some implementations) enclose the memory units 204, the vertical interconnect unit 206, and the processor die 210. In the illustrated implementation, the dies are unencapsulated, e.g., disposed in a gas (e.g., air) cavity within the heat sink 214. In other implementations, as explained below, the processor 210, the memory units 204, and the vertical interconnect unit 206 can be embedded in one or more encapsulating layers disposed within the heat sink 214. In some implementations, fins can be coupled to the heat sink 214 to improve heat dissipation. The fins can be arranged in different patterns, such as straight or curved, to enhance airflow and cooling efficiency. In some implementations, an array of pins (i.e., columns, projections, etc.) can be used instead of fins. The pins can increase the surface area for heat dissipation while maintaining a compact form factor, making them suitable for application with limited space. In some implementations, the heat sink 214 can comprise a liquid cooling heat sink. The heat sink 214 can utilize a liquid coolant, such as water or refrigerant, to transfer heat away from the processor 210. In some implementations, a cooling unit (e.g., a cooling cavity die, which can comprise a silicon die) can be bonded (e.g. direct bonded) to the second side 213 of the processor die 210. Additional details of such bonded cooling units may be found throughout U.S. Patent Publication No. US 2024/0038633, throughout U.S. Patent Publication No. US 2024/0203823, throughout U.S. Patent Publication No. US 2024/0222222A, throughout U.S. patent application No. U.S. Ser. No. 18/394,985, the entire contents of which are incorporated by reference herein in their entirety and for all purposes. The heat sink 214 can comprise various materials, such as metals and ceramics, to optimize thermal conductivity and mechanical strength.

FIG. 4 illustrates a schematic bottom view of the bonded structure 200 of FIG. 3 without the substrate 202. As shown in FIG. 4, a plurality of memory units 204 can be stacked and arranged at a periphery of the processor die 210, and the vertical interconnect unit 206 can be positioned laterally between a first group of memory units 204 (e.g., first memory unit 204a) and a second group of memory units 204 (e.g., second memory unit 204b). Also, although the length of the vertical interconnect unit 206 is shown in FIG. 4 to be significantly smaller than that of the processor die 210, in some implementations, the length of the vertical interconnect unit 206 can be similar in size and/or longer than the processor die 210 in that general direction. The position of the vertical interconnect unit 206 could be symmetric or asymmetric with respect to vertical interconnect unit 206 (e.g., their respective centers can be offset in one or both directions). As mentioned above, stacking and hybrid bonding the memory units 204 to the processor die 210 can improve response time and reduce latency due to shortening the distance between the memory units 204 and the processor die 210. Additionally, stacking the memory units 204 directly onto the processor die 210 reduces the lateral footprint the components.

Terminals located on a bottom surface (e.g., surface opposite of the surface connected to the memory units 204, the vertical interconnect unit 206, and the processor die 210) of the substrate 202 can receive one or more signals. The signal(s) can be communicated through the substrate via conductive traces and vias to the upper surface bonded to the memory units 204 and the vertical interconnect unit 206. The signal(s) can be routed to lower surfaces of the various memory units 204 disposed on the substrate 202 via the embedded conductive traces (e.g., high-speed electrical traces). The signal(s) can be routed to the appropriate memory unit 204 based at least on the memory address and/or memory architecture. The substrate 202 can also perform arbitration to prioritize and schedule memory requests for efficient utilization. Whether through conductive bumps 208 (i.e., flip-chip connections) and/or a hybrid bonding interface, the signal(s) is transferred from the substrate 202 to each memory unit 204. The conductive bumps 208 connecting the memory units 204 to the substrate 202 can be optional. The substrate 202 can also route various signal(s) to the lower surface of the vertical interconnect unit 206 positioned laterally between the memory units 204, which can alleviate bandwidth from the memory units 204. The signal(s) can be communicated through the memory units 204 to the logic controller 205 via one or more vias, which are also in communication with the memory dies 203. The logic controller 205 can manage the signal(s) and/or flow of data between substrate 202 and/or memory dies 203. The logic controller 205 can also process the incoming signals, interpreting commands, and addressing any data.

The signal(s) can be transferred from the logic controller 205 and/or the vertical interconnect unit 206, through a bonding interface, to a lower surface of the processor die 210 corresponding to an active device side. Particularly, the signal(s) can be transferred to the processor die 210 from the logic controller 205 positioned at an upper portion of the memory units 204 such that the logic controller 205 is disposed vertically between the memory dies 203 and the processor die 210. The transfer of signals between the logic controller 205 and the processor die 210 can comprise high speed signaling. In some implementations, the signal transfer between the logic controller 205 and the processor die 210 comprises the majority of any high speed signaling. The logic controller 205, for sending or receiving other signals, can also access the substrate 202 via vertical interconnect unit 206. The logic controller 205 of the memory units 204 can directly interact with the processor die 210. The processor die 210 can access the data from the memory units 204 via the logic controller 205 and can provide the instructions to the logic controller 205. The rest of the signals that processor die 210 can be transferred from the vertical interconnect unit 206. Through connections of the memory units 204 can be used in other ways, e.g. providing power and ground and limited signals. The signal(s) received by the processor 210 can be synchronized and formatted during the transfer so as to be compatible with the processor die 210. The signal(s) can be interpreted by the processor die 210 (i.e., interpreted by integrated memory controller of the processor die 210) and converted into a usable form. The cores of the processor die 210 can utilize the converted data and/or commands. Heat generated from the processor die 210 can be transferred from a backside of the processor die 210 (i.e., opposite the active side contacting the logic controller 205 of the memory units 204) to the heat sink 214. The heat sink 214 can be in proximity and/or contacting the processor die 210. The process described herein can also be reversed such that a signal is generated in the processor die 210, passes through the logic controller 205 and memory dies 203 of the memory units 204, communicated through the substrate 202, and is passed through the terminals of the substrate 202.

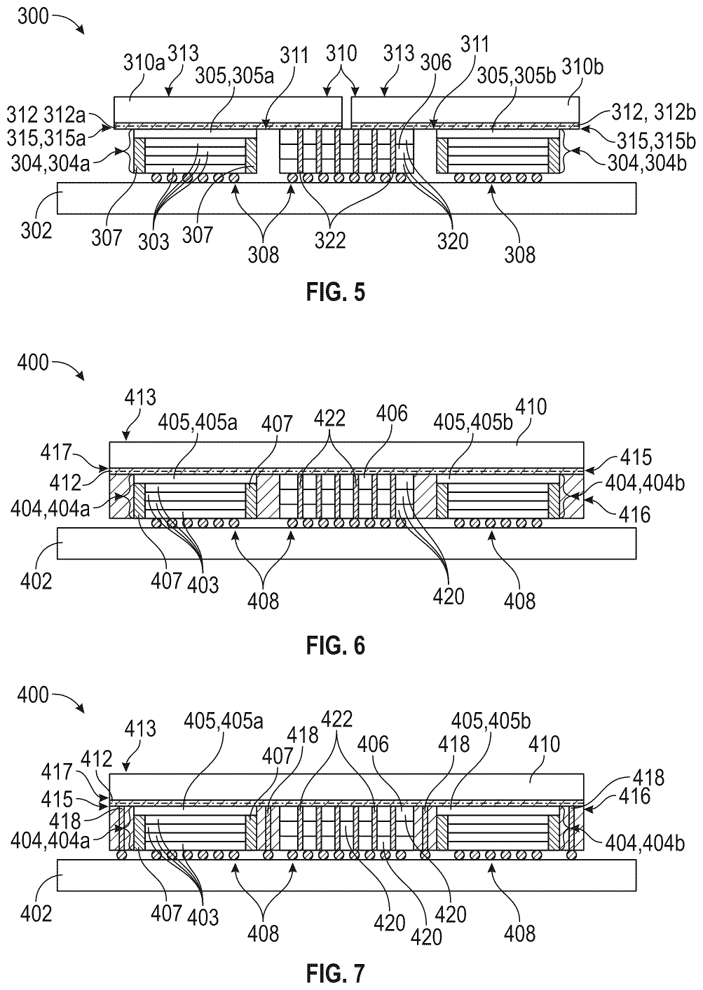

FIG. 5 illustrates a schematic side sectional view of another example implementations of a bonded structure 300. Unless otherwise noted, the components of FIG. 5 can be the same as or generally similar to like-numbered components of FIGS. 3 and 4. For example, the bonded structure 300 can include a substrate 302, memory units 304 (a first memory unit 304a and a second memory unit 304b), a connector unit 306, conductive bumps 308, and a heat sink (not shown).

In FIG. 5, the bonded structure 300 can include dies 310, a first die 310a and/or a second die 310b, which can comprise processor dies, e.g., CPUs, GPUs, etc., as mentioned below. The dies 310 can include a bonding layer 312, such that the first die 310a includes a bonding layer 312a and the second die 310b includes a bonding layer 312b. The first die 310a can be bonded (e.g., directly bonded) at the bonding layer 312a to the first memory unit 304a and the connector unit 306 along a first bonding interface 315a. The second die 310b can also be bonded (e.g., directly bonded) at the bonding layer 312b to the second memory unit 304b and the connector unit 306 along a second bonding interface 315b. The connector unit 306 can connect the first die 310a and the second die 310b. The connector unit 306 can serve as a bridge for lateral communication between the first die 310a and the second processor die 310b. By functioning as a bridge, the connector unit 306 can provide high speed transmission between the first die 310a, the second processor die 310b, the first memory unit 304a and the second memory unit 304b. In some implementations, the first die 310a and the second die 310b can be functionally similar. For example, both the dies 310a and 310b can be CPUs, GPU, NPU, and/or TPUs. But in some other implementations, the first die 310a can be functionally different from the second die 310b. For example, the first die 310a can be a CPU and a second die 310b can be a GPU. In some other examples, the dies 310a and/or 310b can be CPUs, GPUs, NPU, TPUs, switch (e.g. network switch), and/or have one or more other functionalities including peripheral logic, switch, network on chip (NOC), memory, cache (e.g. L1, L2, L3 cache), photonic integrated circuit (PIC), accelerator, accelerator interface fabric, IO interface (e.g. HBM interface, PCIe interface, etc.), SERDES (serializer and deserialize function), etc.

The first memory unit 304a of the memory units 304 can also be bonded to the first die 310a along the first bonding interface 315a. In some implementation, the second memory unit 304b of the memory units 304 can be bonded to the second processor die 310b along the second bonding interface 315b. Each memory unit 304a, 304b can comprise a plurality of (e.g., two, three, four, five, eight, twelve, sixteen, etc.) memory dies 303 (e.g., DRAM dies, NAND dies, etc.) hybrid bonded to and stacked upon each other. The memory units 304 can be encapsulated by an encapsulant 307, such as inorganic dielectric (e.g., silicon oxide, silicon nitride, etc.) or an organic dielectric (e.g., a polymeric molding compound). In some implementations, the memory units 304 can be bonded to a prepared surface of the processors dies 310 using a ZIBOND® or hybrid DBI® technique, or the like (e.g., without adhesive or an intervening layer). Each of the memory units 304 can further include a logic controller 305. The logic controller 305 can manage data communicated to or from the stack of memory dies 303. In some implementation, the first logic controller 305a and the second logic controller 305b of the first memory unit 304a and/or the second memory unit 304b, respectively, can be disposed on (e.g., stacked on top of) the stack of memory dies 303. In some implementations, the processor dies 310 are bonded to the logic controller 305 of the memory units 304 at the bonding layer 312 along the bonding interface 315, bonding surfaces 315a, 315b, such that the logic controller 305 is between the stack of memory dies 303 of the memory units 304 and the processor dies 310. The processor dies 310 can also include a first side 311, a second side 313 opposite the first side 311, and active circuitry (not shown) positioned closer to the first side 311 than the second side 313. In some implementations, the first side 311 is bonded to the memory units 304 and the connector unit 306 (i.e., facedown). In some implementations, dies 310a and 310b can be joined using reconstitution method (i.e. dies are reconstituted on a carrier wafer/panel and then the gap between them is filled with organic or inorganic dielectric). In some embodiments, routing layer can be formed on the reconstituted wafer. Memory units 304 (e.g., memory units 304a and 304b) and vertical interconnect unit 306 are mounted on the processor die (or wafer) 210 and then encapsulated with organic or inorganic dielectric, prior to attaching this molded stack (comprising dies 310, memory units 204. and vertical interconnect unit 306) to the substrate 202.

In some implementations, the connector unit 306 can include a plurality of layers 320 (e.g., one or more dies, laminate layers, etc.) directly hybrid bonded to one another. In some implementations, the connector unit 306 can include a number of dies such that the height of the dies corresponds to a height of the memory units 304, the first memory unit 304a and the second memory unit 304b. In some implementations, the connector unit 306 can comprise an interposer. The connector unit 306 can further include interconnects 322 (e.g., TSVs and/or TEVs) formed within the stack of layers 320. The layers 320 of the connector unit 306 can comprise any suitable material such as silicon or glass. Additionally, the connector unit 306 can include capacitors for a PDN, input/output circuits, and cache memory. A backside of the connector unit 306 can further include routing layers (e.g., RDL, circuitry and/or components) fabricated during the back-end-of-line (BEOL) phase of the manufacturing process to reduce traffic in the connector unit 306.

In some implementations, the bonded structure 300 can include a substrate 302. The first memory unit 304a and the connector unit 306 can be disposed on the substrate 302. In some implementations, a plurality of conductive bumps 308 can be disposed between the substrate 302 and the first memory unit 304a and the connector unit 306. The plurality of conductive bumps 308 can electrically connect the first memory unit 304a and the connector unit 306 to the substrate 302. The plurality of conductive bumps 308 can comprise a conductive adhesive such as solder balls. In some implementations, the second memory unit 304b can be also disposed on the substrate 302. The second memory unit 304b can be laterally spaced from the first memory unit 304a on the substrate 302. Signals between the substrate 302 and the processor dies 310 can pass between the memory units 304 and/or TSVs (e.g., through substrate vias, through silicon vias, etc.) of the connector unit 306. In some implementations, the connector unit 306 can be positioned between the first memory unit 304a and the second memory unit 304b. In some implementations, an underfill 316 is disposed between the substrate 302 and the memory units 304, the first memory unit 304a, the second memory unit 304b, and the connector unit 306. The underfill 316 can comprise an epoxy and/or polymer material to fill a gap between the substrate 302 and the memory units 304 and the connector unit 306. In other implementations, the memory units 304 and the connector unit 306 can be hybrid bonded to the substrate 302.

In various implementations, a heat sink (e.g., a heat sink bar and/or a spreader, see heat sink 214 in FIG. 3) can be mounted to the substrate 302 and disposed over the processor dies 310 to dissipate heat generated by the processor dies 310 and prevent overheating. Similar to heat sink 214, the heat sink can contact a backside (i.e., the second side 313 when the first side 311 is bonded to the memory units 304 and the connector unit 306) of the processor dies 310. The heat sink can comprise a thermally conductive material, such as aluminum or copper, with a large surface area to efficiently transfer heat away from the processor die 310. In some implementations, the heat sink can be attached to the processor dies 310 using a thermally conductive adhesive and/or thermal paste. Once the heat is transferred to the heat sink, the heat then dissipates into the surrounding air through convection. In some implementations, the heat sink 214 can comprise a liquid cooling heat sink. In some implementations, a cooling unit (e.g., a cooling cavity die, which can comprise a silicon die) can be bonded (e.g. direct bonded) to the second side 313 of the dies 310

FIGS. 6, 7, and 8 illustrate schematic perspective views of a bonded structure 400 comprising memory units 404 (e.g. HBMs) and vertical interconnect unit 406 reconstituted on processor 410 (also mentioned herein as “wafer” and/or “processor wafer). In some implementations, processor wafer 410 can be a reconstituted wafer (e.g. comprising processor dies). Unless otherwise noted, the components of FIGS. 6 and 7 can be the same as or generally similar to like-numbered components of FIGS. 3-5. For example, the bonded structure 400 can include a substrate 402, memory dies 403, memory units 404 (a first memory unit 404a and a second memory unit 404b), logic controllers 405 (a first logic controller 405a and a second logic controller 405b), a vertical interconnect unit 406, an encapsulant 407, conductive bumps 408, a processor 410, a bonding layer 412, a heat sink (not shown), bonding interface 415, a plurality of layers 420, and interconnects 422. In FIGS. 6 and 7, the memory units 404 and the vertical interconnect unit 406 can be at least partially embedded in a reconstitution layer 416 (i.e., embedded in an encapsulant). Reconstitution layer 416 can be formed of organic material (e.g. epoxy molding compound, resin, etc.) or inorganic material (e.g. silicon oxide, silicon nitride, etc.). In some implementations, a redistribution layer (RDL) 417 is also formed on processor 410 for electrical connections between the processor 410, memory units 404, and/or the vertical interconnect unit 406. The reconstitution layer 416 can comprise an encapsulant. The encapsulant can comprise one or multiple inorganic dielectric layers (e.g., silicon oxide, silicon nitride, etc.). In some implementations, the one or more inorganic layers can comprise a first thin conformal layer (e.g., silicon nitride) and a second filling layer (e.g., silicon oxide). In other implementations, the encapsulant can comprise one or multiple organic layers (e.g., molding compound, epoxy, etc.). Also, as shown in FIG. 7, conductive vias 418 through the reconstitution layer 416 can provide direct communication and between the substrate 402 and the processor 410. In some implementations, the conductive vias 418 can be disposed at a periphery of the reconstitution layer 416, e.g., between an outer edge of the bonded structure 400 and the memory units 404. In some implementations, the conductive vias 418 can be disposed laterally between the memory units 404 and the vertical interconnect unit 406. In some implementations, the conductive vias 418 can feed power and/or signals to the processor die 410 and/or RDL 417 on the processor die 410. In some implementations, conductive vias 418 through the reconstitution layer 416 can provide power to the RDL 417 on processor 410. In some implementations, the logic controllers 405 can have backside power delivery network (B-PDN), and conductive vias 418 can feed power to the logic controllers 405 from the backside via RDL 417.

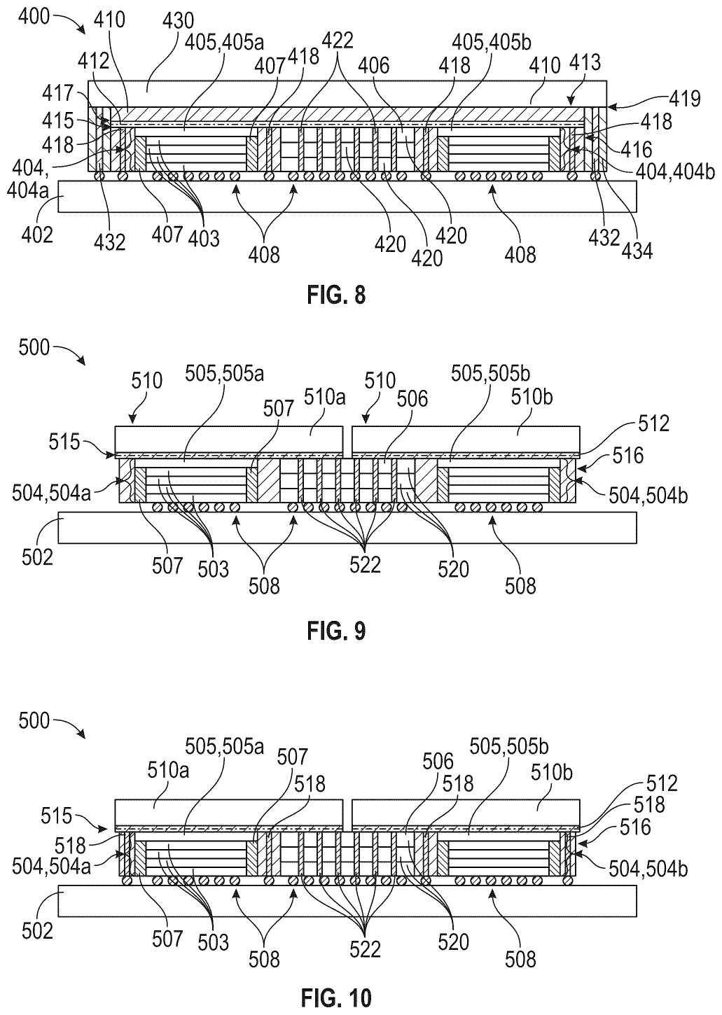

As shown in FIG. 8, the bonded structure 400 can include a backside power delivery network (BS-PDN) and power delivery die 430 disposed over the second side 413 of the processor 410. A reconstitution layer 434 can be formed around the reconstituted processor die 416. The reconstitution layer 434 can be similar and/or identical to the reconstitution layer 416. Power to the power delivery die 430 (and hence to the BS-PDN) can be provided by through dielectric vias (TDVs) 432 at the periphery of the power delivery die 430. The TDVs 432 can extend through the reconstitution layer 434. A redistribution layer (RDL) 419 can be formed between the processor 410 and the power delivery die 430, which can be connected to TDVs 432 and deliver power from the second side 413 of processor 410 via the BS-PDN formed on the second side 413. The power delivery die 430 can include power and ground lines, capacitors for a smooth (or ripple free) PDN, input/output circuits, and/or cache memory. Beneficially, the power delivery die 430 can deliver power and/or ground to the backside power delivery network (BS-PDN) formed on the second side 413 (e.g., a backside) of the processor die 410. In some implementations, the conductive vias 418 can convey the power and/or ground to and/or from the active circuitry at or near the first side 411 of the processor die 410. In some implementations, the bonded structure 400 can include one or more wire bonds (not shown) electrically connected to the power delivery die 430 to transfer power to the power delivery die 430. The power delivery die 430 can manage power distribution across the bonded structure 400 so that the different components (i.e., memory units 404 and/or processor 410) receive the required amount of power while maintaining efficient operation and preventing localized voltage drops. As with the growing complexity of designs and system requirements, managing power delivery efficiently can assist in providing power to the bonded structure 400, particularly for devices with fine pitches. The power delivery die 430 can comprise metal traces and/or power grid structures that are designed to distribute power from an external power supply to different regions of the structure. The power delivery die 430 can be designed to account for factors such as current density, electromigration effects, and thermal considerations to optimize power distribution. The power delivery die 430 can also include voltage regulators or decoupling capacitors to regulate voltages to stabilize the power supply and reduce noise.

FIGS. 9 and 10 illustrate schematic perspective views of another implementations of a bonded structure 500 comprising reconstituted HBMs and vertical interconnect units. Unless otherwise noted, the components of FIGS. 9 and 10 can be the same as or generally similar to like-numbered components of FIGS. 3-7. For example, the bonded structure 500 can include a substrate 502, memory dies 503, memory units 504 (a first memory unit 504a and a second memory unit 504b), logic controllers 505 (a first logic controller 505a and a second logic controller 505b), a connector unit 506, an encapsulant 507, conductive bumps 508, a processor dies 510 (a first processor die 510a and a second processor die 510b), a bonding layer 512, a heat sink (not shown), a bonding interface 515, a plurality of layers 520, and/or interconnects 522. In FIGS. 9 and 10, the memory units 504 and the connector unit 506 can be at least partially embedded in a reconstitution layer 516 (i.e., embedded in an encapsulant). The reconstitution layer 516 can comprise an encapsulant similar to that of reconstitution layer 416. Also, as shown in FIG. 10, conductive vias 518 through the reconstitution layer 516 can provide direct communication between the substrate 502 and the processor dies 510. In some implementations, the conductive vias 518 can be disposed at a periphery of the reconstitution layer 516. In some implementations, the dies 510 can be mounted on the reconstituted wafer 516 (comprising memory units 504, and connector unit 506). In some implementations, die 510 can be encapsulated after attaching to the bottom reconstituted wafer 516. In some other implementations, dies 510a and 510b are reconstituted to form a reconstituted wafer 516, and memory units 504 and connector unit 506 are reconstituted (e.g. encapsulated) on the reconstituted processor wafer 516.

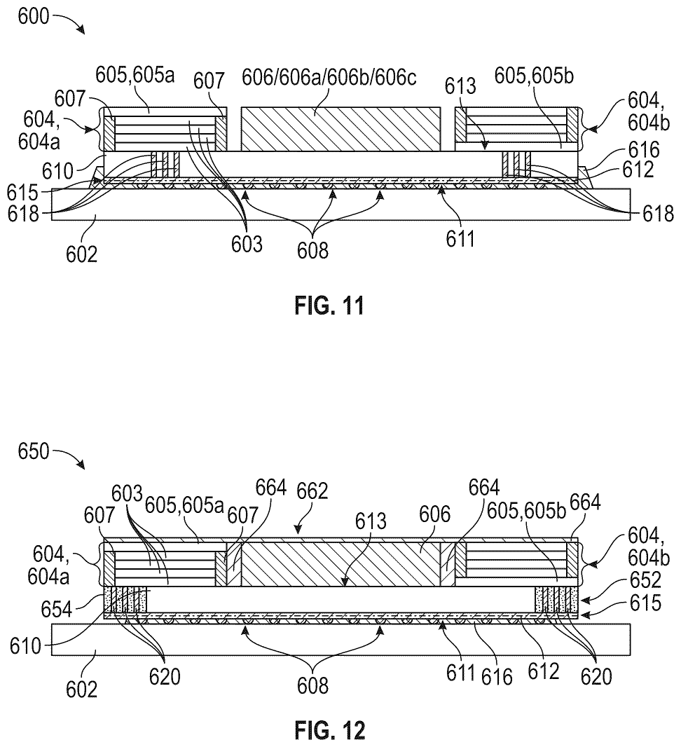

FIG. 11 illustrates a schematic side view of another implementation of a bonded structure 600. Unless otherwise noted, the components of FIG. 11 can be the same as or generally similar to like-numbered components of FIGS. 3-10. As illustrated in FIG. 11, the bonded structure 600 can include a substrate 602, similar to any of the substrates mentioned above, and a processor 610 mounted to the substrate 602. The processor die 610 can include a first side 611 and a second side 613 (also mentioned herein as a “backside”) opposite the first side 611. In some implementations, the processor 610 can include active circuitry (not shown) positioned closer to the first side 611 than the second side 613 and vice versa. In some implementations, the second side 613 can have one or more routing layers (e.g. RDL). In some implementations, the first side 611 is bonded to the substrate 602 at a bonding layer 612 along a bonding interface 615, shown in a face down configuration in FIG. 11 in which the active side of the processor die 610 is bonded to the substrate 602. The processor die 610 can comprises at least one of a SOC, a CPU, and a GPU. In some implementations, the processor 610 can comprise a thinned processor such that backside material is removed from the backside of the die. Thinning the processor 610 can reduce the overall thickness allowing for a smaller and more compact packaging. Additionally, by thinning the processor 610, heat dissipation properties can be enhanced since the processer provides a shorter thermal path to more easily transfer heat generated by the processor 610 to a cooling unit 606b and/or the surrounding environment, aiding in cooling. Overall performance qualities can also be improved by reducing the distance between different components of the die leading to faster signal propagation and reduced electrical resistance.

The processor 610 can be electrical and mechanical communication with the substrate 602. In some implementations, the processor 610 can be mounted to the substrate 602 by way of conductive bumps 608 (e.g., solder balls and/or another conductive adhesive). In some implementations, an underfill 616 is disposed between the substrate 602 and the processor 610. The underfill 616 can comprise an epoxy and/or polymer material to fill a gap between the substrate 602 and processor 610. In other implementations, the bonding layer 612 and the processor 610 can be hybrid bonded to the substrate 602 along the bonding interface 615. The processor 610 can further include one or more TSVs 618 (e.g., through substrate vias, through silicon vias, etc.) extending through a periphery of the processor 610.

The bonded structure 600 can also include memory units 604, each memory unit 604a, 604b comprising a plurality of (e.g., two, three, four, five, eight, twelve, sixteen, etc.) memory dies 603 (e.g., DRAM dies) bonded (e.g., directly bonded) to and stacked on one another. Each of the memory units 604 can further include a logic controller 605. The logic controller 605 can manage data communicated to or from the stack of memory dies 603. In some implementation, the first logic controller 605a and the second logic controller 605b of the first memory unit 604a and/or second memory unit 604b, respectively, can be disposed on (e.g., stacked on top of) the stack of memory dies 603. In some implementation, the first logic controller 605a and the second logic controller 605b of the first memory unit 604a and/or second memory unit 604b, respectively, can be positioned below the stack of memory dies 603 (i.e., positioned between the memory dies 603 and the processor 610). In some implementations, the logic controller 605 of the first memory unit 604a can be disposed on the memory dies 603 and the logic controller 605 of the second memory unit 604b can be position below the memory dies 603, and vice versa.

As illustrated in FIG. 11, in implementations in which the memory dies 603 are positioned between the logic controller(s) 605 and the processor 610, TSVs can extend through the memory dies 603 to connect the logic controller 605 to the TSVs of the processor die 610 (e.g., TSVs 618 discussed below). In some implementations, the logic controller(s) 605 can be positioned on the bottom of the memory unit 604 (e.g., the memory dies 603 are stacked on top of the logic controller 605, with the logic controller 605 bonded to the processor) such that the logic controller 605 can communicate directly to the active side of the processor 610 using TSVs 618 formed in the processor, but without use of TSVs through the memory dies 603. The memory units 604 can be laterally spaced from one another on the processor 610. For example, the first memory unit 604a can be disposed on a first end of the processor die 610 and the second memory unit 604b can be disposed on a second end opposite the first end of the processor die. The memory units 604 can be encapsulated by an encapsulant 607, such as inorganic dielectric (e.g., silicon oxide, silicon nitride, etc.) or an organic dielectric (e.g., a polymeric molding compound).

The memory units 604 can be bonded (e.g., hybrid bonded) to the second side 613 of the processor 610 such that the memory units 604 are stacked and connected directly to the processor 610. In some implementations, the memory units 604 are bonded to a backside of the processor 610. As mentioned previously, by hybrid bonding the processor 610 to the memory units 604, the need for an interposer and/or bridge is eliminated for processor/HBM interaction. Stacking the memory units 604 directly on the processor 610 can reduce transmission losses and thus improve latency. The TSVs 618 can route signals and power/ground lines from the processor 610 to the memory units 604.

A die 606 can also be directly hybrid bonded to the processor 610. The die 606 can be mounted to the second side 613 of the processor 610. In some implementations, the die 606 can be positioned between the first memory unit and the second memory unit along the processor 610. In various embodiments, the illustrated die 606 can comprise one or more of a power redistribution element 606a, the cooling unit 606b, or a dummy die 606c. In some implementations, processor die 610 has backside power delivery network (BS-PDN) implementations in which power is delivered predominantly from the backside of the processor die 610 and signal is delivered predominantly from the front side of the processor die 610. In some implementations, the die 606 can comprise the power redistribution element 606a. The power redistribution element 606a can include power and ground lines, capacitors for a smooth (or ripple free) PDN, input/output circuits, and cache memory. Beneficially, in implementations in which the die 606 comprises the power redistribution element 606a, the die 606 can deliver power and/or ground to the backside power delivery network formed on the second side 613 (e.g., a backside) of the processor die 610. In some implementations, the TSVs 618 can convey the power and/or ground to and/or from the active circuitry at or near the first side 611 of the processor die 610. In some implementations, the bonded structure 600 can include one or more wire bonds (not shown) electrically connected to the power redistribution element 606a to transfer power to the power redistribution element 606a. The power redistribution element 606a can manage power distribution across the bonded structure 600 so that the different components (i.e., memory units 604 and processor 610) receive the required amount of power while maintaining efficient operation and preventing localized voltage drops. As with the growing complexity of designs and system requirements, managing power delivery efficiently can assist in preventing performance degradation, reliability issues, and potential damage to the bonded structure 600. The power redistribution element 606a can comprise metal traces and/or power grid structures that are designed to distribute power from an external power supply to different regions of the structure. The power redistribution element 606a can be designed to account for factors such as current density, electromigration effects, and thermal considerations to optimize power distribution. The power redistribution element 606a can also include voltage regulators or decoupling capacitors to regulate voltages to stabilize the power supply and reduce noise.

In some implementations, the die 606 can, alternatively or additionally, comprise the cooling unit 606b within the bonded structure 600 that is designed to enhance the thermal management capabilities of the bonded structure 600 by facilitating the transfer of heat. The cooling unit 606b can be bonded (e.g. direct bonded) to the processor die 610. The cooling unit 606b can comprise a cavity and/or recessed area within the bonded structure 600 that allows for the placement of cooling elements, such as heat sinks and/or liquid cooling systems, to assist in regulating the temperature of the components (e.g., memory units 604 and processor 610). For example, in some implementations, the cooling unit 606b can comprise a liquid pathway therethrough through which a cooling liquid can be delivered to convey heat away from heat sources in the system, e.g., away from the processor die 610. In some implementations, the cooling unit 606b (e.g., silicon die) is bonded (e.g., direct bonded) to the power distribution die 606a described above, and the stack formed from the combined power redistribution element 606a and cooling unit 606b can be bonded (e.g., direct bonded) to the backside 613 of the processor die 610. Additional details of such cooling units 606b may be found throughout U.S. Patent Publication No. US 2023/0154828, the entire contents of which are incorporated by reference herein in their entirety and for all purposes. Additionally or alternatively, the die 606 can comprise the dummy die 606c in which the die 606 can be a non-functional die (with no active circuitry) that does not perform a function related to the bonded structure 600. The dummy die 606c can improve thermal management by reducing temperature gradients across the bonded structure 600 and maintaining more uniform thermal conditions. The dummy die 606c can also serve as a support structure to improve structural integrity of the bonded structure 600 and to smooth out or reduce stresses imparted on the dies (e.g., from the encapsulant).

A heat sink (not shown) (e.g., a heat sink bar, a spreader, and/or a cooling manifold) can be mounted and disposed over the memory units 604 and the die 606 to dissipate heat generated by the components. The heat sink can comprise a thermally conductive material, such as aluminum or copper, with a large surface area to efficiently transfer heat away. In some implementations, the heat sink can be attached using a thermally conductive adhesive and/or thermal paste, to ensure good thermal contact. Once the heat is transferred to the heat sink, the heat then dissipates into the surrounding air through convection.

FIG. 12 illustrates a schematic side view of another implementation of a bonded structure 650. Unless otherwise noted, the components of FIG. 12 can be the same as or generally similar to like-numbered components of FIG. 11. For example, the bonded structure 650 can include a substrate 602, memory units 604 (a first memory unit 604a and a second memory unit 604b), a die 606, conductive bumps 608, a processor 610, and a heat sink (not shown). In FIG. 12, the bonded structure 650 can include a reconstituted die 652 mounted to the substrate 602 to which the reconstituted die 652 (or reconstituted wafer 652 comprising processor die) is affixed (e.g., via a flip chip, ball grid array (BGA), etc.). In some implementations, the reconstituted die 652 is mounted to the substrate 602 by conductive bumps 608. Additionally, in some implementations, the reconstituted die 652 can be hybrid bonded to the substrate 602. The reconstituted die 652 can include the processor 610 such that the processor 610 is at least partially encapsulated by an encapsulant 654, such as inorganic dielectric (e.g., silicon oxide, silicon nitride, etc.) or an organic dielectric (e.g., a polymeric molding compound). In some implementations, the encapsulant 654 can be disposed along a side surface of the processor 610. Additionally, one or more through dielectric vias (TDSs) 620 can be formed around a periphery along the side surface of the 610 through the encapsulant 654. The encapsulant 654 can be a conventional organic dielectric (e.g., molding compound) of a type typically used to encapsulate electrical components. The encapsulant 654 can be an epoxy encapsulant or any other suitable encapsulant. In some implementations, the second side of the reconstituted wafer 652 can have one or more routing layers (e.g. RDL).

The bonded structure 650 can also include a memory units 604 and the die 606 mounted to the reconstituted die 652. The die 606 of FIG. 12, which can be similar and/or identical to the die 606 described with respect to FIG. 11, can comprise a power redistribution element 606a, a cooling unit 606b, and/or a dummy die 606c. The power redistribution element 606a can include power and ground lines, capacitors for a smooth (or ripple free) PDN, input/output circuits, and cache memory. Beneficially, in implementations in which the die 606 comprises the power redistribution element 606a, the die 606 can deliver power and/or ground to the backside power delivery network formed on the second side 613 (e.g., a backside) of the processor die 610. As mentioned above with respect the bonded structure 600, the cooling unit 606b within the bonded structure 650 can be designed to enhance the thermal management capabilities of the bonded structure 650 by facilitating the transfer of heat. The cooling unit 606b can be bonded (e.g. direct bonded) to the processor die 610. The cooling unit 606b can comprise a cavity and/or recessed area within the bonded structure 650 that allows for the placement of cooling elements, such as heat sinks and/or liquid cooling systems, to assist in regulating the temperature of the components (e.g., memory units 604 and processor 610). Additionally or alternatively, the die 606 can comprise the dummy die 606c in which the die 606 can be a non-functional die (with no active circuitry) that does not perform a function related to the bonded structure 600. The dummy die 606c can improve thermal management by reducing temperature gradients across the bonded structure 600 and maintaining more uniform thermal conditions. The dummy die 606c can also serve as a support structure to improve structural integrity of the bonded structure 600 and to smooth out or reduce stresses imparted on the dies (e.g., from the encapsulant).

In some implementations, the bonded structure 650 can also include a reconstituted layer 662 disposed over and mounted to the reconstituted die 652. The reconstituted layer 662 can include the memory units 604 and the die 606 at least partially encapsulated in a second encapsulant 664. The second encapsulant 664 can be similar and/or identical to the encapsulant 654. In some implementations, the reconstituted layer 662 can be direct hybrid bonded to the reconstituted die 652.

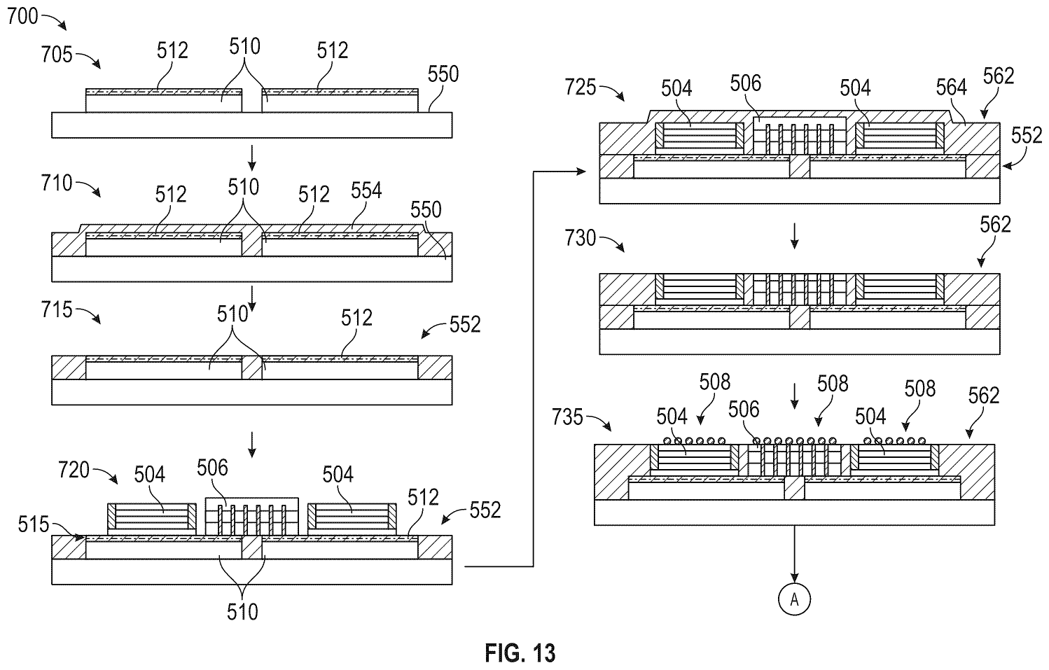

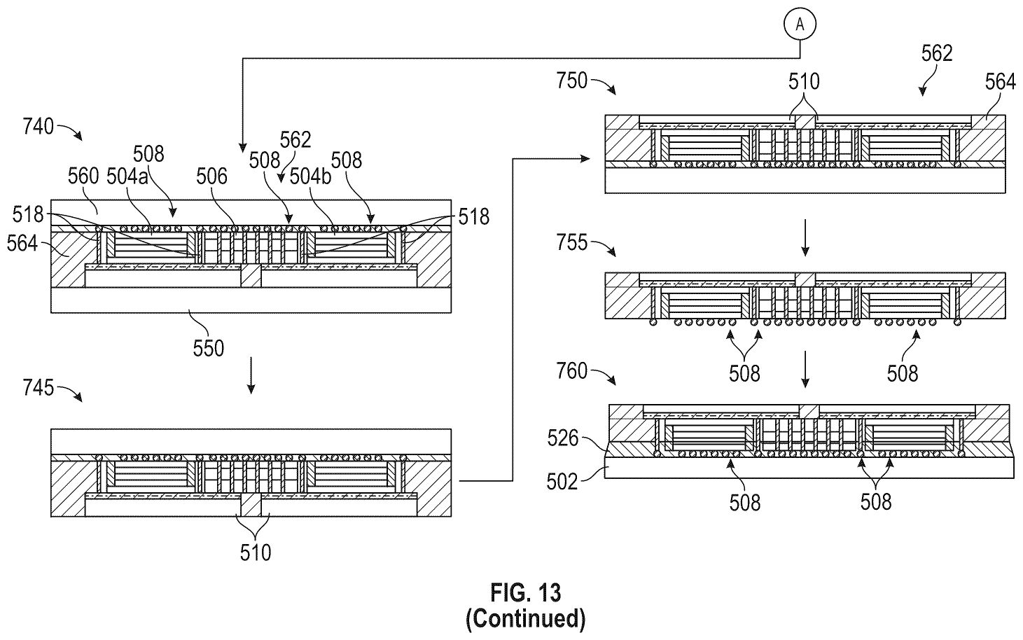

FIG. 13 is a graphical flow diagram illustrating an example process 700 for assembling the bonded structure 500. At step 705, processor dies 510 having bonding layers 512 can be disposed (e.g., bonded) to a carrier 550. In some implementations, the carrier 550 can be a sacrificial carrier. In some implementations, the carrier 550 can act as a thermal management feature. For example, the carrier 550 can be a cooling cavity element (e.g., a wafer and/or die) and/or a heat spreader component, similar to heat sink 214, which can remain in or on the finished bonded structure 500. As explained herein, the processor dies 510 can be direct bonded to the carrier 550 in some implementations (e.g., the processor dies 510 and the carrier 550) can be suitably prepared for bonding. Nonconductive and conductive regions of the processor dies 510 and the carrier 550 can be directly bonded to one another without intervening adhesives and without application of external pressure.

At step 710, the processor dies 510 are mounted to the carrier 550 and exposed surfaces of the carrier 550 can be at least partially encapsulated by an encapsulant 554 (e.g., protective material) to form a reconstituted die 552. Beneficially, the encapsulant 554 can protect the edges of the processor dies 510 from chipping during planarization or other processing steps. The encapsulant 554 can be disposed along one or more top and/or side surfaces of the processor dies 510 and between adjacent processor dies 510. The encapsulant 554 can be a conventional organic dielectric (e.g., molding compound) of a type typically used to encapsulate electrical components. The encapsulant 554 can be an epoxy molding compound or any other suitable encapsulant. In some other embodiments, encapsulant 554 can comprise inorganic material (e.g. silicon oxide, silicon nitride, etc.).

At step 715, at least an exposed surface of the reconstituted die 552 can be planarized to a high degree of smoothness to allow for direct hybrid bonding. For example, in some implementations, a chemical mechanical polishing (CMP) technique can be used to remove some of the encapsulant 554, which can expose the processor dies 510. Advantageously, the encapsulant 554 can protect the processor dies 510 during the planarization process. As explained herein, additional components can be stacked on and connected to (e.g., directly bonded with) the processor dies 510. In some implementations, one or more redistribution layers can be formed on the exposed surface of the reconstituted wafer along with a hybrid bonding layer.

At step 720, the memory units 504 and the connector unit 506 can be hybrid bonded to the exposed surface of the reconstituted die 552 comprising the processor dies 510. In some other embodiments, the memory units 504 and the connector unit 506 can be hybrid bonded to the RDL layer formed on the reconstituted wafer.

At step 725, the memory units 504 and the connector unit 506 can be at least partially encapsulated in a second encapsulant 564 to for the reconstituted layer 562. At step 730, an exposed surface of the reconstituted layer 562 can be planarized to a high degree of smoothness for bonding.

At step 735, the conductive bumps 508 can be attached to an upper surface the memory units 504 and the connector unit 506 exposed through the planarized exposed surface of the reconstituted layer 562. In some implementations, the conductive bumps 508 can comprise solder balls or another conductive adhesive. In other implementations, at step 735, the upper surface of the memory units 504 and the connector unit 506 can be prepared for hybrid bonding.

At step 740, a second carrier 560 (i.e., a temporary or handling carrier) can be temporarily attached to the conductive bumps 508. For example, the second carrier 560 can be attached to the conductive bumps 508 by a temporary adhesive layer that can be softened or dissolved, using a vacuum chuck to hold the partially assembled bonded structure 500 to the second carrier 560, electrostatic bonding through electrostatic forces generated by a high voltage, and/or permanently attaching the second carrier 560 to the conductive bumps 508 and removing the second carrier 560 through processes such as grinding, etching, and/or mechanical peeling. The second carrier 560 can provide mechanical support during subsequent steps of the process 700. For example, the second carrier 560 can assist in thinning or bonding of different components of the partially assembled bonded structure 500 by providing additional support and/or stability. In some implementations, the conductive vias 518 (e.g., TSVs) can be formed in the second encapsulant 564 of the reconstituted layer 562. The conductive vias 518 can be formed around a periphery of the memory units 504, first memory unit 504a and second memory unit 504b. Additionally, the conductive vias 518 can be formed between the memory units 504, the first memory unit 504a, the second memory unit 504b, and the connector unit 506.

At step 745, the carrier 550, shown in step 740, can be grinded down and/or removed to expose the processor dies 510. By grinding down the carrier 550, the processor dies 510 can be mounted to and/or integrated into another component or package. Additionally, grinding the carrier 550 can remove excess material that can interfere with packaging processes and/or device performance. In other implementations, the carrier 550 can act as a thermal management feature. For example, the carrier 550 can be a cooling cavity element (e.g., a wafer and/or die) and/or a heat spreader component, similar to heat sink 214, which can remain in or on the finished bonded structure 500.

At step 750, the encapsulant 554 of the reconstituted die 552 and the processor dies 510 can be polished to achieve a thickness (i.e., a desired or particular thickness). Polishing can remove excess material and reduce the overall thickness which can improve performance and/or satisfy dimension requirements.

At step 755, the second carrier 560 can be detached from the conductive bumps 508. As mentioned above, the second carrier 560 can be detached by a variety of methods. Prior to singulation, the remaining components of the partially assembled bonded structure 500 can then be tested for functionality. In some implementations, only known good dies (KGDs) may be selected for mounting. The conductive bumps 508 can serve as probe pads to determine known good die pairs while still at the wafer level. Multiple dies comprising bonded structure 500 can be singulated for mounting on another substrate, board, or another package. At step 760, the substrate 502 can be attached (e.g., bonded) to the conductive bumps 508. In some implementations, the underfill 526 can be disposed between the substrate 502 and the conductive bumps 508.

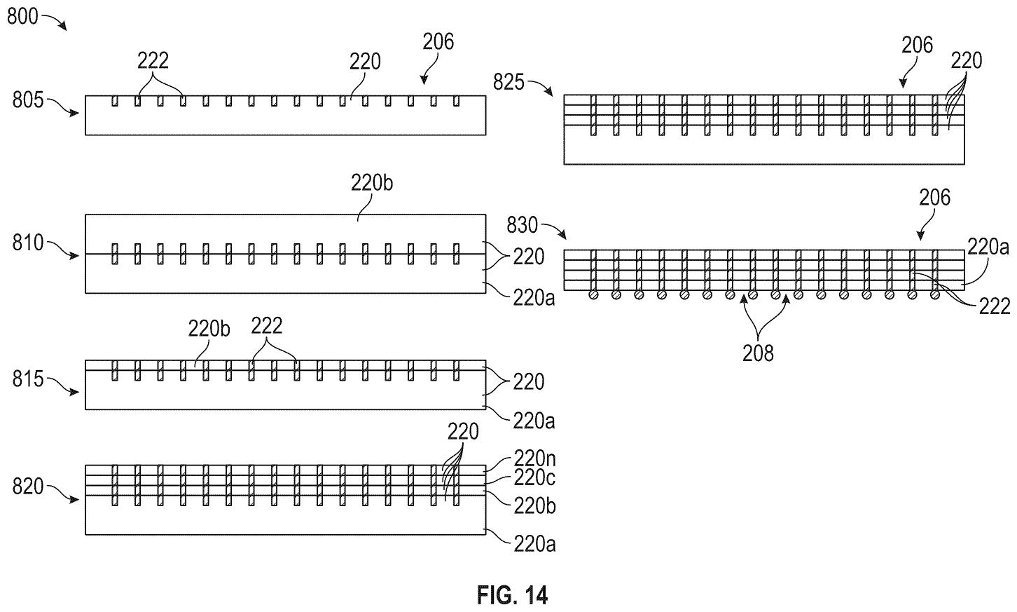

FIG. 14 is a graphical flow diagram illustrating an example process 800 for assembling any of the vertical interconnect units, for example, the vertical interconnect units 206, 406. However, process 800 can apply to any and all of the connector units 306, 506 contained herein. At step 805, the vertical interconnects 222 (e.g., TSVs, traces, and/or any combination) can be formed in the layer 220 (e.g., die) of the vertical interconnect unit 206. In some implementations, the vertical interconnects 222 can have a shallow and/or fine pitch. The size (diameter) of the vertical interconnects 222 can be approximately less than 10 μm, approximately less than 10 μm, approximately less than 8 μm, approximately less than 6 μm, approximately less than 5 μm, or approximately less than 3 μm. In some implementations, the vertical interconnects 222 can have a depth of approximately between 1 μm to 200 μm, approximately 2 μm to 175 μm, approximately 3 μm to 150 μm, approximately 4 μm to 125 μm, or 5 μm to 100 μm. In some implementations, the vertical interconnects 222 can have a pitch less than at least 30 μm, less than at least 25 μm, less than at least 22.5 μm, less than at least 20 μm, less than at least 17.5 μm, less than at least 15 μm, or less than at least 10 μm. The layer 220 can comprise any suitable semiconductor substrate (e.g., silicon), a dielectric substrate (e.g., glass), a ceramic substrate, etc.

At step 810, two layers 220 (e.g., a base layer 220a and a second layer 220b having vertical interconnects 222 formed therein) can by hybrid bonded together along a bonding interface. The two layers 220 can be bonded with or without interconnect landing pads (e.g., area on a semiconductor die and/or substrate where a TSVs terminates and makes electrical contact with other circuitry and/or other TSVs). At step 815, the second layer 220b can be grinded to expose and/or reveal the vertical interconnects 222.

At step 820, additional layers 220 (e.g., 220c . . . 220n) can be sequentially stacked upon the second layer 220b to match or approximately match a thickness (i.e., height) of memory units 204, 304, 404, 504, 604. Step 815 can be repeated for each additional layer 220 (e.g., 220c . . . 220n).

At step 825, conductive features can be disposed at a front side of the vertical interconnect unit 206 forming a front side bonding interface. The conductive features can include exposed ends of TSVs (e.g., openings or channel created through the layer 220 for forming electrical connections), contact pads for hybrid bonding techniques, and/or microbumps. In some implementations, the front side of the vertical interconnect unit 206 can include a redistribution layer comprising metal traces and vias that are used to redistribute electrical connections.

At step 830, a backside of the vertical interconnect unit 206 can be grinded to expose and/or reveal vertical interconnects 222 formed in the base layer 220a. In some implementations, the vertical interconnect unit 206 can be attached to a carrier for ease of processing. Backside conductive features (e.g., conductive bumps 208) can be disposed onto the backside of the vertical interconnect unit 206. In some implementations, the backside of the vertical interconnect unit 206 can include a second redistribution layer comprising metal traces and vias that are used to redistribute electrical connections. The vertical interconnect unit 206 can also be singulated which can be determined by size or operation constraints.

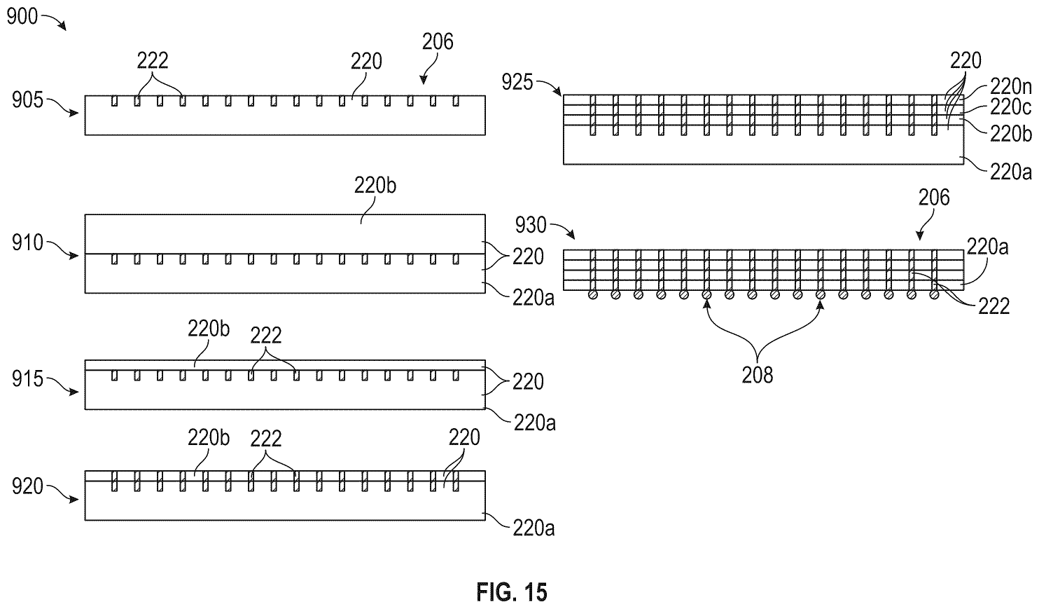

FIG. 15 is a graphical flow diagram illustrating an example process 900 for assembling any of the connector units, for example, the vertical interconnect unit 206, 406. However, process 900 can apply to any and all of the connector units 306, 506 contained herein. At step 905, the vertical interconnects 222 (e.g., TSVs, traces, and/or any combination) can be formed in a layer 220 (e.g., die) of the vertical interconnect unit 206. In some implementations, the vertical interconnects 222 can have a shallow and/or fine pitch. The size (diameter) of the vertical interconnects 222 can be approximately less than 10 μm, approximately less than 10 μm, approximately less than 8 μm, approximately less than 6 μm, approximately less than 5 μm, or approximately less than 3 μm. In some implementations, the vertical interconnects 222 can have a depth of approximately between 1 μm to 200 μm, approximately 2 μm to 175 μm, approximately 3 μm to 150 μm, approximately 4 μm to 125 μm, or 5 μm to 100 μm. In some implementations, the vertical interconnects 222 can have a pitch less than at least 30 μm, less than at least 25 μm, less than at least 22.5 μm, less than at least 20 μm, less than at least 17.5 μm, less than at least 15 μm, or less than at least 10 μm. The layer 220 can comprise any suitable material such as silicon, glass, ceramic,

At step 910, a base layer 220a having the vertical interconnects 222 formed therein can be bonded to a second layer 220b (e.g. a wafer) along a bonding interface. The two layers 220 (i.e., base layer 220a and second layer 220b) can be directly bonded to one another (e.g., by uniform nonconductive bonding). At step 915, the second layer 220b can be grinded to thin the thickness of the second layer 220b. At step 920, openings can be formed in the layer 220b, and a conductive metal (e.g., copper) is filled in the openings to form vertical interconnects 222, which can connect to the vertical interconnects 222 formed in the base layer 220a.

At step 925, additional layers 220 (e.g., 220c . . . 220n) can be sequentially stacked upon the second layer 220b to match or approximately match a thickness (i.e., height) of memory units 204, 304, 404, 504, 604. Step 925 can be repeated for each additional layer 220 (e.g., 220c . . . 220n). Additionally, conductive features can be disposed at a front side of the vertical interconnect unit 206 forming a front side bonding interface. The conductive features can include TSVs tips (i.e., openings or channel created through the layer 220 for forming electrical connections), contact pads for hybrid bonding techniques, and/or microbumps. In some implementations, the front side of the vertical interconnect unit 206 can include a redistribution layer comprising metal traces and vias that are used to redistribute electrical connections.

At step 930, a backside of the vertical interconnect unit 206 can be grinded to expose and/or reveal vertical interconnects 222 formed in the base layer 220a. In some implementations, the vertical interconnect unit 206 can be attached to a carrier for ease of processing. Backside conductive features (e.g., conductive bumps 208) can be disposed onto the backside of the vertical interconnect unit 206. In some implementations, the backside of the vertical interconnect unit 206 can include a second redistribution layer comprising metal traces and vias that are used to redistribute electrical connections. The vertical interconnect unit 206 can also be singulated which can be determined by size or operation constraints.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1608a and/or 1608b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

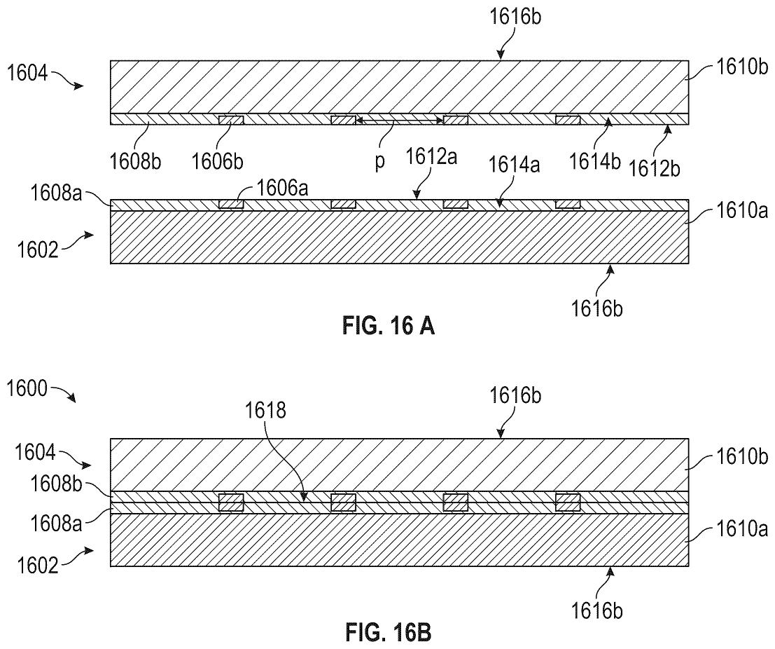

FIGS. 16A and 16B schematically illustrate cross-sectional side views of first and second elements 1602, 1604 prior to and after, respectively, a process for forming a directly bonded structure, and more particularly a hybrid bonded structure, according to some embodiments. In FIG. 16B, a bonded structure 1600 comprises the first and second elements 1602 and 1604 that are directly bonded to one another at a bond interface 1618 without an intervening adhesive. Conductive features 1606a of a first element 1602 may be electrically connected to corresponding conductive features 1606b of a second element 1604. In the illustrated hybrid bonded structure 1600, the conductive features 1606a are directly bonded to the corresponding conductive features 1606b without intervening solder or conductive adhesive.

The conductive features 1606a and 1606b of the illustrated embodiment are embedded in, and can be considered part of, a first bonding layer 1608a of the first element 1602 and a second bonding layer 1608b of the second element 1604, respectively. Field regions of the bonding layers 1608a, 1608b extend between and partially or fully surround the conductive features 1606a, 1606b. The bonding layers 1608a, 1608b can comprise layers of non-conductive materials suitable for direct bonding, as described above, and the field regions are directly bonded to one another without an adhesive. The non-conductive bonding layers 1608a, 1608b can be disposed on respective front sides 1614a, 1614b of base substrate portions 1610a, 1610b.

The first and second elements 1602, 1604 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1602, 1604, and back-end-of-line (BEOL) interconnect layers over such semiconductor portions. The bonding layers 1608a, 1608b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1610a, 1610b, and can electrically communicate with at least some of the conductive features 1606a, 1606b. Active devices and/or circuitry can be disposed at or near the front sides 1614a, 1614b of the base substrate portions 1610a, 1610b, and/or at or near opposite backsides 1616a, 1616b of the base substrate portions 1610a, 1610b. In other embodiments, the base substrate portions 1610a, 1610b may not include active circuitry, but may instead comprise dummy substrates, passive interposers, passive optical elements (e.g., glass substrates, gratings, lenses), etc. The bonding layers 1608a, 1608b are shown as being provided on the front sides of the elements, but similar bonding layers can be additionally or alternatively provided on the back sides of the elements.

In some embodiments, the base substrate portions 1610a, 1610b can have significantly different coefficients of thermal expansion (CTEs), and bonding elements that include such different based substrate portions can form a heterogenous bonded structure. The CTE difference between the base substrate portions 1610a and 1610b, and particularly between bulk semiconductor (typically single crystal) portions of the base substrate portions 1610a, 1610b, can be greater than 5 ppm/° C. or greater than 10 ppm/° C. For example, the CTE difference between the base substrate portions 1610a and 1610b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 1610a, 1610b can comprise optoelectronic single crystal materials, including perovskite materials, that are useful for optical piezoelectric or pyroelectric applications, and the other of the base substrate portions 1610a, 1610b comprises a more conventional substrate material. For example, one of the base substrate portions 1610a, 1610b comprises lithium tantalate (LiTaO3) or lithium niobate (LiNbO3), and the other one of the base substrate portions 1610a, 1610b comprises silicon (Si), quartz, fused silica glass, sapphire, or a glass. In other embodiments, one of the base substrate portions 1610a, 1610b comprises a III-V single semiconductor material, such as gallium arsenide (GaAs) or gallium nitride (GaN), and the other one of the base substrate portions 1610a, 1610b can comprise a non-III-V semiconductor material, such as silicon (Si), or can comprise other materials with similar CTE, such as quartz, fused silica glass, sapphire, or a glass. In still other embodiments, one of the base substrate portions 1610a, 1610b comprises a semiconductor material and the other of the base substrate portions 1610a, 1610b comprises a packaging material, such as a glass, organic or ceramic substrate.

In some arrangements, the first element 1602 can comprise a singulated element, such as a singulated integrated device die. In other arrangements, the first element 1602 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1604 can comprise a singulated element, such as a singulated integrated device die. In other arrangements, the second element 1604 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 1602, 1604 are shown, any suitable number of elements can be stacked in the bonded structure 1600. For example, a third element (not shown) can be stacked on the second element 1604, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1602. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1608a, 1608b, the bonding layers 1608a, 1608b can be prepared for direct bonding. Non-conductive bonding surfaces 1612a, 1612b at the upper or exterior surfaces of the bonding layers 1608a, 1608b can be prepared for direct bonding by polishing, for example, by chemical mechanical polishing (CMP). The roughness of the polished bonding surfaces 1612a, 1612b can be less than 30 Å rms. For example, the roughness of the bonding surfaces 1612a and 1612b can be in a range of about 0.1 Å rms to 15 Å rms, 0.5 Å rms to 10 Å rms, or 1 Å rms to 5 Å rms. Polishing can also be tuned to leave the conductive features 1606a, 1606b recessed relative to the field regions of the bonding layers 1608a, 1608b.

Preparation for direct bonding can also include cleaning and exposing one or both of the bonding surfaces 1612a, 1612b to a plasma and/or etchants to activate at least one of the surfaces 1612a, 1612b. In some embodiments, one or both of the surfaces 1612a, 1612b can be terminated with a species after activation or during activation (e.g., during the plasma and/or etch processes). Without being limited by theory, in some embodiments, the activation process can be performed to break chemical bonds at the bonding surface(s) 1612a, 1612b, and the termination process can provide additional chemical species at the bonding surface(s) 1612a, 1612b that alters the chemical bond and/or improves the bonding energy during direct bonding. In some embodiments, the activation and termination are provided in the same step, e.g., a plasma to activate and terminate the surface(s) 1612a, 1612b. In other embodiments, one or both of the bonding surfaces 1612a, 1612b can be terminated in a separate treatment to provide the additional species for direct bonding. In various embodiments, the terminating species can comprise nitrogen. For example, in some embodiments, the bonding surface(s) 1612a, 1612b can be exposed to a nitrogen-containing plasma. Other terminating species can be suitable for improving bonding energy, depending upon the materials of the bonding surfaces 1612a, 1612b. Further, in some embodiments, the bonding surface(s) 1612a, 1612b can be exposed to fluorine. For example, there may be one or multiple fluorine concentration peaks at or near a bond interface 1618 between the first and second elements 1602, 1604. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1600, the bond interface 1618 between two non-conductive materials (e.g., the bonding layers 1608a, 1608b) can comprise a very smooth interface with higher nitrogen (or other terminating species) content and/or fluorine concentration peaks at the bond interface 1618. In some embodiments, the nitrogen and/or fluorine concentration peaks may be detected using various types of inspection techniques, such as SIMS techniques. The polished bonding surfaces 1612a and 1612b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1608a and 1608b can be directly bonded to one another without an adhesive. In some embodiments, the elements 1602, 1604 are brought together at room temperature, without the need for application of a voltage, and without the need for application of external pressure or force beyond that used to initiate contact between the two elements 1602, 1604. Contact alone can cause direct bonding between the non-conductive surfaces of the bonding layers 1608a, 1608b (e.g., covalent dielectric bonding). Subsequent annealing of the bonded structure 1600 can cause the conductive features 1606a, 1606b to directly bond.

In some embodiments, prior to direct bonding, the conductive features 1606a, 1606b are recessed relative to the surrounding field regions, such that a total gap between opposing contacts after dielectric bonding and prior to anneal is less than 15 nm, or less than 10 nm. Because the recess depths for the conductive features 1606a and 1606b can vary across each element, due to process variation, the noted gap can represent a maximum or an average gap between corresponding conductive features 1606a, 1606b of two joined elements (prior to anneal). Upon annealing, the conductive features 1606a and 1606b can expand and contact one another to form a metal-to-metal direct bond.

During annealing, the conductive features 1606a, 1606b (e.g., metallic material) can expand while the direct bonds between surrounding non-conductive materials of the bonding layers 1608a, 1608b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1606a, 1606b can comprise discrete pads, contacts, electrodes, or traces at least partially embedded in the non-conductive field regions of the bonding layers 1608a, 1608b. In some embodiments, the conductive features 1606a, 1606b can comprise exposed contact surfaces of TSVs (e.g., through silicon vias).

As noted above, in some embodiments, in the elements 1602, 1604 of FIG. 16A prior to direct bonding, portions of the respective conductive features 1606a and 1606b can be recessed below the non-conductive bonding surfaces 1612a and 1612b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1606a, 1606b or to average depths of the recesses relative to local non-conductive field regions. Even for an individual conductive feature 1606a, 1606b, the vertical recess can vary across the feature, and so can be measured at or near the lateral middle or center of the cavity in which a given conductive feature 1606a, 1606b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 1606a, 1606b across the direct bond interface 1618 (e.g., small or fine pitches for regular arrays).

In some embodiments, a pitch p of the conductive features 1606a, 1606b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1606a and 1606b to one of the lateral dimensions (e.g., a diameter) of the bonding pad is less than 20, or less than 10, or less than 5, or less than 3 and sometimes desirably less than 2. In various embodiments, the conductive features 1606a and 1606b and/or traces can comprise copper or copper alloys, although other metals may be suitable, such as nickel, aluminum, or alloys thereof. The conductive features disclosed herein, such as the conductive features 1606a and 1606b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1602, 1604, as shown, the orientations of one or more conductive features 1606a, 1606b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1606b in the bonding layer 1608b (and/or at least one internal conductive feature, such as a BEOL feature) of the upper element 1604 may be tapered or narrowed upwardly, away from the bonding surface 1612b. By way of contrast, at least one conductive feature 1606a in the bonding layer 1608a (and/or at least one internal conductive feature, such as a BEOL feature) of the lower element 1602 may be tapered or narrowed downwardly, away from the bonding surface 1612a. Similarly, any bonding layers (not shown) on the backsides 1616a, 1616b of the elements 1602, 1604 may taper or narrow away from the backsides, with an opposite taper orientation relative to front side conductive features 1606a, 1606b of the same element.

As described above, in an anneal phase of hybrid bonding, the conductive features 1606a, 1606b can expand and contact one another to form a metal-to-metal direct bond. In some embodiments, the materials of the conductive features 1606a, 1606b of opposite elements 1602, 1604 can interdiffuse during the annealing process. In some embodiments, metal grains grow into each other across the bond interface 1618. In some embodiments, the metal is or includes copper, which can have grains oriented along the 111 crystal plane for improved copper diffusion across the bond interface 1618. In some embodiments, the conductive features 1606a and 1606b may include nanotwinned copper grain structure, which can aid in merging the conductive features during anneal. There is substantially no gap between the non-conductive bonding layers 1608a and 1608b at or near the bonded conductive features 1606a and 1606b. In some embodiments, a barrier layer may be provided under and/or laterally surrounding the conductive features 1606a and 1606b (e.g., which may include copper). In other embodiments, however, there may be no barrier layer under the conductive features 1606a and 1606b.

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain implementations and examples, it will be understood by those skilled in the art that the various implementations of the systems and processes extend beyond the specifically disclosed implementations to other alternative implementations and/or uses of the systems and processes and obvious modifications and equivalents thereof. In addition, while several variations of the implementations of the systems and processes have been shown and described in detail, other modifications, which are within the scope of this disclosure, will be readily apparent to those of skill in the art based upon this disclosure. It is also contemplated that various combinations or sub-combinations of the specific features and implementations of the implementations may be made and still fall within the scope of the disclosure. It should be understood that various features and implementations of the disclosed implementations can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative implementations, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate implementations also may be implemented in combination in a single implementations. Conversely, various features that are described in the context of a single embodiment also may be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain implementations include, while other implementations do not include, certain features, elements and/or states. Thus, such conditional language is not generally intended to imply that features, elements and/or states are in any way required for one or more embodiments.

While certain implementations have been described, these implementations have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative implementations may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further implementations. The accompanying claims and their equivalents are intended to cover such forms or modifications as would fall within the scope and spirit of the disclosure.

Several illustrative examples of bonded structures and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the implementations shown herein but are to be accorded a fair interpretation consistent with this disclosure, the principles and the novel features disclosed herein.

1-127. (canceled)

128. A bonded structure comprising:
a substrate;
a first memory unit disposed on the substrate, the first memory unit comprising:
a first stack of memory dies; and
a first logic controller to manage data communicated to or from the first stack of memory dies, wherein the first logic controller is disposed on the first stack of memory dies;
a processor die hybrid bonded to the first memory unit along a bonding interface; and
a vertical interconnect connecting the substrate to the processor die.

129. The bonded structure of claim 128, further comprising a heat sink disposed over a backside of the processor die.

130. The bonded structure of claim 128, further comprising a plurality of conductive bumps disposed between the first memory unit and the substrate and between the vertical interconnect and the substrate, the plurality of conductive bumps electrically connecting the first memory unit to the substrate and electrically connecting the vertical interconnect to the substrate, wherein the plurality of conductive bumps comprise solder bumps.

131. The bonded structure of claim 128, further comprising:
a second memory unit disposed on the substrate, the second memory unit comprising:
a second stack of memory dies; and
a second logic controller to manage data communicated to or from the second stack of memory dies, wherein the second logic controller is disposed on the second stack of memory dies, wherein the second logic controller, and wherein the second memory unit is laterally spaced from the first memory unit on the substrate.

132. The bonded structure of claim 131, wherein the vertical interconnect is positioned between the first memory unit and the second memory unit.

133. The bonded structure of claim 128, wherein the vertical interconnect comprises an interposer.

134. The bonded structure of claim 128, wherein the vertical interconnect comprises through encapsulant vias (TEVs).

135. The bonded structure of claim 128, wherein the processor die comprises a first side, a second side opposite the first side, and active circuitry positioned closer to the first side than the second side, and wherein the first side is bonded to the first memory unit.

136. The bonded structure of claim 135, wherein the first logic controller of the first memory unit is hybrid bonded to the first side of the processor die.

137. The bonded structure of claim 128, wherein the first memory unit and the vertical interconnect are at least partially embedded in an encapsulant.

138. The bonded structure of claim 137, wherein one or more vias extend through the encapsulant to directly connect the processor die and the substrate.

139. A bonded structure comprising:
a first memory unit comprising:
a first stack of memory dies; and
a first memory logic controller to manage data communicated to or from the first stack of memory dies, wherein the first memory logic controller is disposed on the first stack of memory dies; and
a processor die bonded to the first memory logic controller along a bonding interface, wherein the first memory logic controller is between the first stack of memory dies and the processor die.

140. The bonded structure of claim 139, further comprising:
a substrate, wherein the first memory unit is disposed on the substrate;
a vertical interconnect connecting the substrate to the processor die, the vertical interconnect bonded to the processor die; and
a plurality of conductive bumps disposed between the substrate and the first memory unit and the vertical interconnect, the plurality of conductive bumps electrically connecting the first memory unit and electrically connecting the vertical interconnect to the substrate, wherein the plurality of conductive bumps comprise solder bumps.

141. The bonded structure of claim 140, wherein the first memory logic controller is hybrid bonded to the processor die along the bonding interface.

142. The bonded structure of claim 140, further comprising:
a second memory unit disposed on the substrate, the second memory unit comprising:
a second stack of memory dies; and
a second memory logic controller to manages data communicated to or from the second stack of memory dies wherein the second logic controller is disposed on the second stack of memory dies;
wherein the second memory logic controller is bonded to the processor die along the bonding interface; and
wherein the second logic controller is between the second stack of memory dies and the processor die;
wherein the second memory unit is laterally spaced from the first memory unit on the substrate.

143. The bonded structure of claim 139, further comprising a heat sink disposed over a backside of the processor die.

144. The bonded structure of claim 139, wherein the processor die is hybrid bonded to the first memory logic controller along the bonding interface.

145. A bonded structure comprising:
a processor die comprising a first side, a second side opposite the first side, and active circuitry positioned closer to the first side than the second side;
a first memory unit bonded to the first side of the processor die along a bonding interface, the first memory unit comprising:
a first stack of memory dies; and
a first logic controller to manages data communicated to or from the first stack of memory dies, wherein the first logic controller is disposed on the first stack of memory dies; and
a heat sink disposed over the second side of the processor die.

146. The bonded structure of claim 145, further comprising:
a substrate, wherein the first memory unit is disposed on the substrate;
a vertical interconnect connecting the substrate to the processor die, the vertical interconnect bonded to the processor die along the bonding interface; and
a plurality of conductive bumps disposed between the substrate and the memory unit and between the substrate and the vertical interconnect, the plurality of conductive bumps electrically connecting the memory unit and the vertical interconnect to the substrate, wherein the plurality of conductive bumps comprise solder bumps.

147. The bonded structure of claim 146, further comprising:
a second memory unit disposed on the substrate, the second memory unit comprising:
a second stack of memory dies; and
a second logic controller to manage data communicated to or from the second stack of memory dies, wherein the second logic controller is disposed on the second stack of memory dies;
wherein the second memory unit is laterally spaced from the first memory unit on the substrate.

148. The bonded structure of claim 147, wherein the vertical interconnect is positioned between the first memory unit and the second memory unit.

149. The bonded structure of claim 145, wherein the processor die is hybrid bonded to the first logic controller along a bonding interface.

150. The bonded structure of claim 145, wherein one or more vias extend through an encapsulant to directly connect the processor die to a substrate.
